(19) United States
(12) Patent Application Publication
(10) Pub. No.: US 2025/0324870 A1
(43) Pub. Date: Oct. 16, 2025

(54) DISPLAY DEVICE

(71) Applicant: Sharp Display Technology Corporation, Kameyama City, Mie (JP)

(72) Inventors: Tetsuo FUJITA, Kameyama City, Mie (JP); Yukinobu NAKATA, Kameyama City, Mie (JP); Tetsunori TANAKA, Kameyama City, Mie (JP)

(21) Appl. No.: 18/865,013

(22) PCT Filed: Jul. 5, 2022
(86) PCT No.: PCT/JP2022/026660

§ 371 Date: Nov. 12, 2024

(51) Int. Cl. H10K 59/131; G06F 3/044; H10K 59/40; H10K 59/80

(52) U.S. Cl. CPC H10K 59/131; G06F 3/0446; H10K 59/40; H10K 59/871

(57) ABSTRACT

An organic EL display device includes a light-emitting element layer supported by a substrate layer and containing a plurality of organic EL elements. This display device has a frame area around a display area. A touch panel line is provided in the frame area, the touch panel line extending so as to straddle a first and a second frame-shaped damming wall surrounding the display area from the display area side toward outside the frame area. An organic layer spreading in the display area is provided internal to the first and the second damming wall. The first and the second damming wall have such a recess that a portion thereof where the touch panel line extends is lower in height than another portion thereof.

### TECHNICAL FIELD

The present disclosure relates to display devices.

### BACKGROUND ART

Organic EL display devices that include organic electroluminescence (electro luminescence; hereinafter, “EL”) elements have been in practical use for some time. In a known structure for organic EL display devices, organic EL elements are covered, and hence sealed, with a sealing film. For example, Patent Literature 1 discloses a sealing structure in which the sealing film is formed by stacking at least one planarization resin layer and at least one barrier layer. In this sealing structure, an annular damming portion surrounding an electronic element portion is formed on a base body, and a planarization resin layer is formed internal to the damming portion.

### CITATION LIST

### Patent Literature

Patent Literature 1: Japanese Unexamined Patent Application Publication No. 2012-253036

### SUMMARY OF INVENTION

### Technical Problem

When the sealing structure disclosed in Patent Literature 1 is adopted in an organic EL display device, the planarization resin layer is formed by applying a liquid material, for example, by inkjet printing technology or with a dispenser and thereafter curing the applied liquid material. The damming portion is a wall body for damming up the wet-spreading liquid material from which the planarization resin layer is to be formed. Therefore, the damming portion preferably has a large height, with a view to reliably damming up the liquid material, and is designed to be, for example, as relatively high as approximately a few micrometers.

When an organic EL display device with such a damming portion is used as an on-cell touch-panel-equipped display device, the touch panel is fabricated on the sealing film. In such a case, wiring needs to be drawn out from a touch area where a touch position is detected to a frame area in the touch panel. This wiring is formed so as to straddle the damming portion. In such a case, the resist used as a mask in patterning this wiring flows from the top face of the damming portion before being exposed to light and hence thins down on the top face. Therefore, the wiring could undesirably break on the top portion of the damming portion during the etching while the wiring is being formed.

The technique of the present disclosure has an object to restrain the wiring from breaking on the wall body in the frame area of the display device while the wiring is being formed.

### Solution to Problem

The technique of the present disclosure is directed to display devices. A display device in accordance with the technique of the present disclosure has: a display area in which an image is displayed; and a frame area provided around the display area. In the frame area, are there provided: a wall body shaped like a frame and provided around the display area; and a wiring line extending so as to straddle the wall body from a display area side toward outside the frame area. The wall body has such a recess that a portion of the wall body where the wiring line extends is lower in height than another portion of the wall body.

### ADVANTAGEOUS EFFECTS OF INVENTION

The technique of the present disclosure enables restraining the wiring from breaking on the wall body in the frame area of the display device while the wiring is being formed.

### BRIEF DESCRIPTION OF DRAWINGS

FIG. 1 is a schematic plan view of an exemplary structure of an organic EL display device in accordance with an embodiment.

FIG. 2 is a cross-sectional view of the organic EL display device taken along line II-II shown in FIG. 1.

FIG. 3 is a schematic plan view of an exemplary structure of the display panel.

FIG. 4 is a schematic plan view of a structure of a touch panel.

FIG. 5 is a plan view of exemplary pixels and various exemplary display-use wiring lines both in a portion, of a display area, that is surrounded by V in FIG. 3.

FIG. 6 is a plan view of exemplary pixels and exemplary display-use wiring lines both in a portion, of the display area, that corresponds to FIG. 5.

FIG. 7 is a cross-sectional view of the organic EL display device taken along line VII-VII shown in FIG. 5.

FIG. 8 is an equivalent circuit diagram of an exemplary pixel circuit.

FIG. 9 is a cross-sectional view of an exemplary drawn-out configuration of touch panel lines in an organic EL display device in accordance with an embodiment.

FIG. 10 is a plan view of an exemplary configuration of an intersecting portion where a touch panel line intersects with a first damming wall and a second damming wall in an organic EL display device in accordance with an embodiment.

FIG. 11 is a cross-sectional view of the organic EL display device taken along line XI-XI shown in FIG. 10.

FIG. 12 is a cross-sectional view of the organic EL display device taken along line XII-XII shown in FIG. 10.

FIG. 13 is a cross-sectional view of the organic EL display device taken along line XIII-XIII shown in FIG. 10.

FIG. 14 is a cross-sectional view of a portion corresponding to FIG. 11, illustrating, as an example, resist having been applied in patterning touch panel lines in the manufacturing of an organic EL display device in accordance with an embodiment.

FIG. 15 is a cross-sectional view of a portion corresponding to FIG. 12, illustrating, as an example, resist having been applied in patterning touch panel lines in the manufacturing of an organic EL display device in accordance with an embodiment.

FIG. 16 is a cross-sectional view of a portion corresponding to FIG. 13, illustrating, as an example, resist having been applied in patterning touch panel lines in the manufacturing of an organic EL display device in accordance with an embodiment.

FIG. 17 is a cross-sectional view of a portion corresponding to FIG. 13, illustrating, as an example, resist having been developed in patterning touch panel lines in the manufacturing of an organic EL display device in accordance with an embodiment.

FIG. 18 is a cross-sectional view of a portion corresponding to FIG. 13, illustrating, as an example, touch panel lines having been patterned in the manufacturing of an organic EL display device in accordance with an embodiment.

FIG. 19 is a plan view of an exemplary configuration of an intersecting portion where a touch panel line intersects with a first damming wall and a second damming wall in an organic EL display device in accordance with a first variation example.

FIG. 20 is a cross-sectional view of an organic EL display device taken along line XX-XX shown in FIG. 19.

FIG. 21 is a cross-sectional view of a portion corresponding to FIG. 20, illustrating, as an example, resist having been applied in patterning touch panel lines in the manufacturing of the organic EL display device in accordance with the first variation example.

FIG. 22 is a cross-sectional view of a portion corresponding to FIG. 20, illustrating, as an example, resist having been developed in patterning touch panel lines in the manufacturing of the organic EL display device in accordance with the first variation example.

FIG. 23 is a cross-sectional view of a portion corresponding to FIG. 20, illustrating, as an example, touch panel lines having been patterned in the manufacturing of the organic EL display device in accordance with the first variation example.

FIG. 24 is a plan view of an exemplary configuration of an intersecting portion where a touch panel line intersects with a first damming wall and a second damming wall in an organic EL display device in accordance with a second variation example.

FIG. 25 is a cross-sectional view of an exemplary drawn-out configuration of touch panel lines in an organic EL display device in accordance with a third variation example.

FIG. 26 is a cross-sectional view of an exemplary layered structure of a first damming wall, a second damming wall, and a third damming wall in the organic EL display device in accordance with the third variation example.

FIG. 27 is a cross-sectional view of an exemplary layered structure of a portion, of the first damming wall, the second damming wall, and the third damming wall, where touch panel lines run in the organic EL display device in accordance with the third variation example.

FIG. 28 is a cross-sectional view of a portion corresponding to FIG. 12, illustrating, as an example, resist having been applied in patterning touch panel lines in the manufacturing of an organic EL display device in accordance with a comparative example.

FIG. 29 is a cross-sectional view of a portion corresponding to FIG. 12, illustrating, as an example, touch panel lines having been patterned in the manufacturing of an organic EL display device in accordance with a comparative example.

### DESCRIPTION OF EMBODIMENTS

The following describes illustrative embodiments with reference to drawings. The following embodiments take an organic EL display device as an example of a display device in accordance with the technique of the present disclosure. Note that the drawings have been prepared to illustrate the concepts of the technique of the present disclosure. Therefore, the drawings may exaggerate or simplify dimensions, ratios, or numbers to facilitate the understanding of the technique of the present disclosure.

Throughout the following embodiments, a structural member such as a film, a layer, or an element may be described as being disposed, provided, or formed on another structural member such as a film, a layer, or an element not only when the former structural member sits directly on the latter structural member, but also when these structural members are separated by another, intervening structural member such as a film, a layer, or an element.

In addition, throughout the following embodiments, a structural member may be described as being connected to another structural member when these structural members are electrically connected together unless otherwise mentioned explicitly. This language may be used not only when the structural members are directly connected, but also when the structural members are indirectly connected via yet another structural member, without departing from the scope of the technique of the present disclosure. The language may be used also when a structural member is integrated with another structural member, in other words, a structural member partially constitutes another structural member.

In addition, throughout the following embodiments, a structural member may be described as being in the same layer as another structural member when these structural members are formed in the same process. A structural member may be described as underlying/being below another structural member when the former structural member is formed in an earlier process or step than is the latter structural member. A structural member may be described as overlying/being on/being above another structural member when the former structural member is formed in a later process or step than is the other structural member.

In addition, throughout the following embodiments, a structural member may be described as being identical or equivalent to another structural member not only when these structural members are completely identical or equivalent, but also when the structural members are substantially identical or equivalent where they may vary within the range of manufacturing variations and tolerances.

In addition, in the following embodiments, the ordinal numbers, “first,” “second,” “third,” and the like, are used to distinguish between the structural members to which these numbers are assigned and do not limit their number or establish any order between them.

### Embodiment

An organic EL display device 1 in accordance with the present embodiment is applicable to various devices and apparatuses including mobile devices such as multifunctional mobile phones called smartphones and tablet terminals, personal computers (PCs), and television units. The organic EL display device 1 in accordance with the present example is a display device with a touch panel that allows the user to make inputs by touching the display screen.

### Structure of Organic EL Display Device

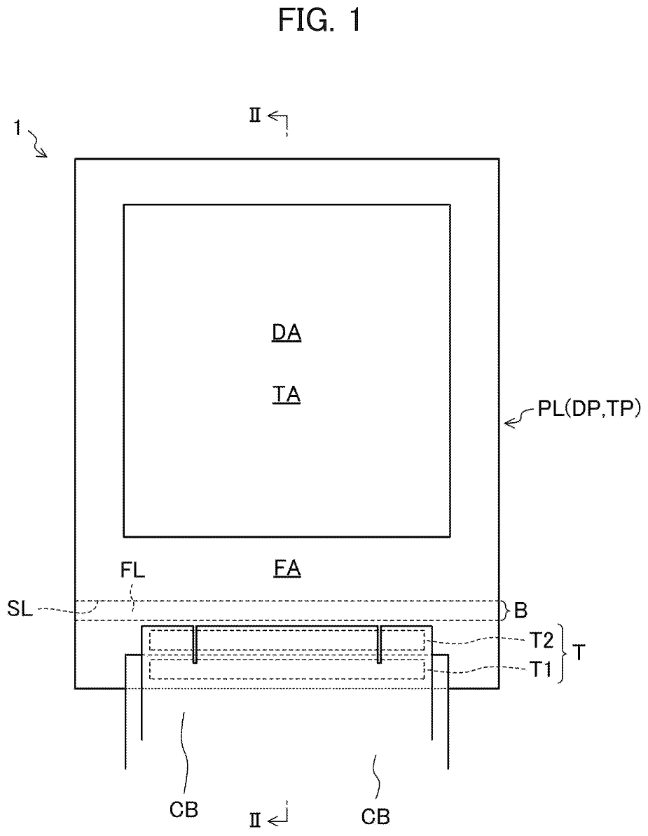

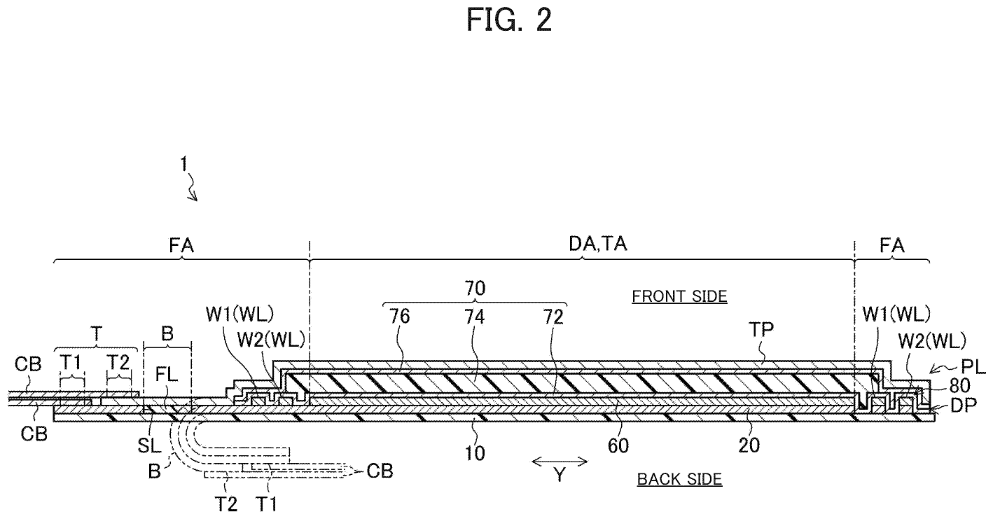

The organic EL display device 1 has a function of detecting a touch position on a screen where images are displayed while displaying images. Referring to FIGS. 1 and 2, the organic EL display device 1 includes a display panel DP and a touch panel TP. The display panel DP and the touch panel TP form a panel body PL. On the front side of the panel body PL, there are provided a polarizer and a cover panel (not shown) in this order.

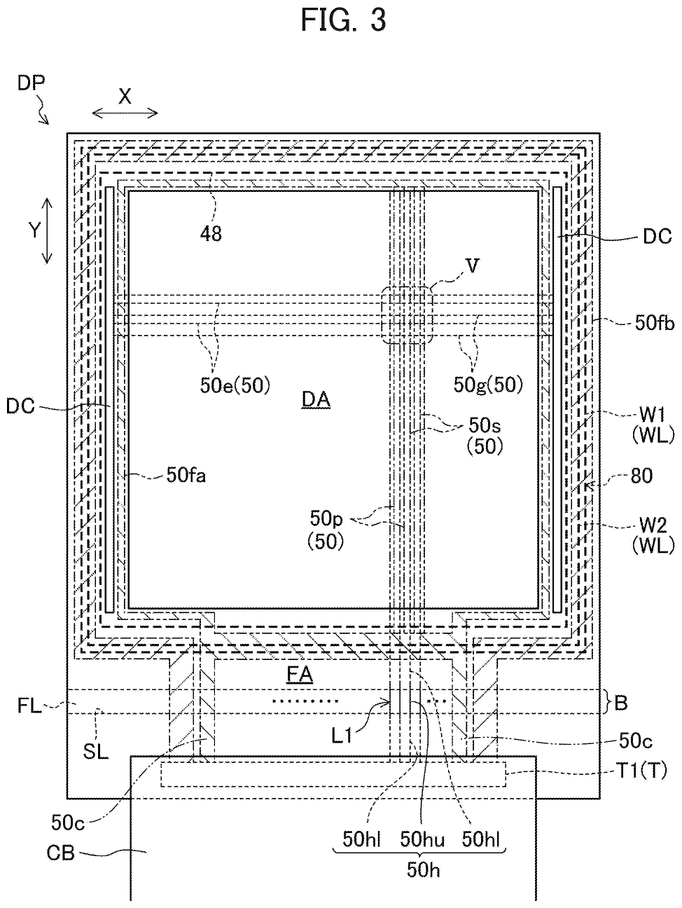

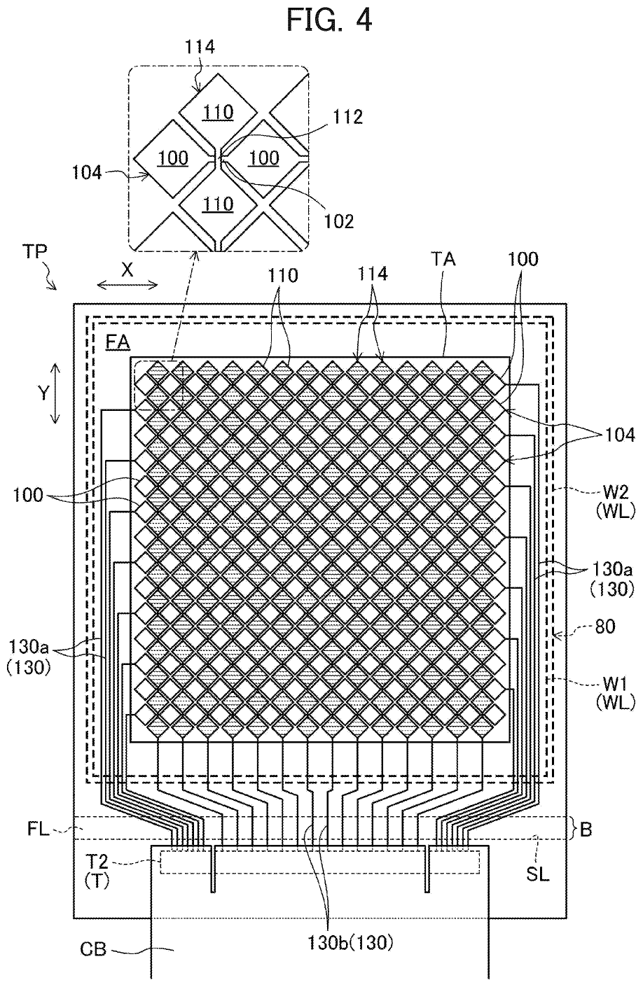

The organic EL display device 1 has a display area DA, a touch area TA, and a frame area FA. The display panel DP includes the display area DA and the frame area FA (see FIG. 3). The touch panel TP includes the touch area TA and the frame area FA (see FIG. 4). The display area DA and the touch area TA are specified to have the same size and disposed in the same location so as to overlap each other. The frame area FA is provided around the display area DA and the touch area TA.

The display area DA is an area where images are displayed. The display area DA provides a screen. The display area DA is, for example, shaped like a rectangle. The display area DA may have a generally rectangular shape such as a shape with at least one of the sides being arc-shaped, a shape with at least one of the corners being arc-shaped, or a shape with at least one of the sides being notched or may have any other shape.

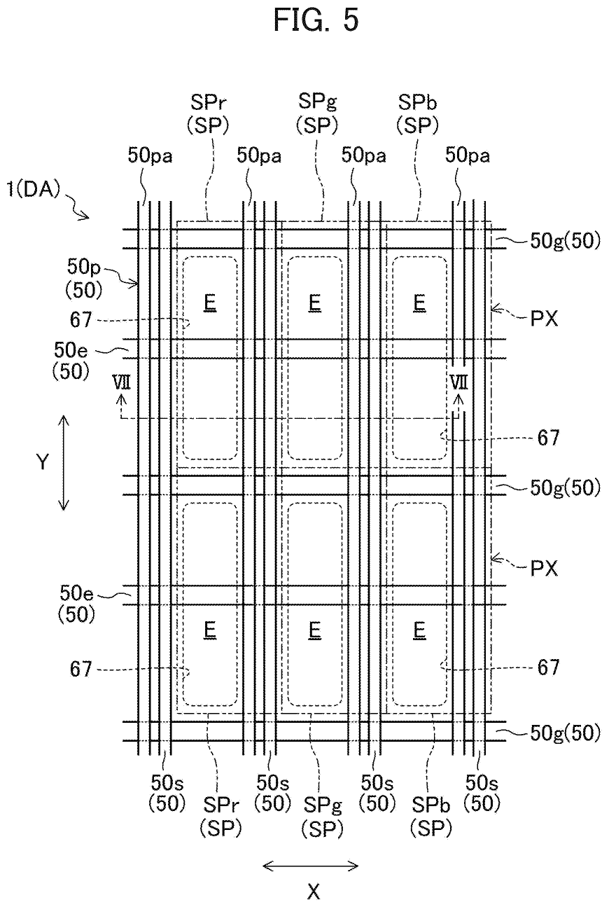

Referring to FIG. 5, the display area DA includes a plurality of pixels PX. The plurality of pixels PX are arranged in a matrix. Each pixel PX includes three subpixels SP. The three subpixels SP are a subpixel SPr that has a light-emitting region E that emits red light, a subpixel SPg that has a light-emitting region E that emits green light, and a subpixel SPb that has a light-emitting region E that emits blue light. These three subpixels SPr, SPg, and SPb are arranged in, for example, stripes.

The touch area TA shown in FIGS. 1 and 2 is an area where a touch position is detected at which a contact body comes into contact with the organic EL display device 1. The contact body is, for example, the user's finger or a stylus. The touch area TA is shaped like, for example, a rectangular frame. The touch area TA has a shape that corresponds to the shape of the display area DA. In other words, the touch area TA may have the aforementioned generally rectangular shape or may have any other shape.

The frame area FA is an area that provides a non-display section other than the screen. The frame area FA is shaped, for example, like a rectangular frame. The frame area FA may be shaped like a non-rectangular frame. The frame area FA includes a terminal section T and a bending portion B. The terminal section T is provided for establishing connections to external circuits. The terminal section T includes a first terminal section T1 and a second terminal section T2.

The first terminal section T1 and the second terminal section T2 are provided in a portion that forms a side of the frame area FA. The first terminal section T1 is located near the outer periphery of the frame area FA. The first terminal section T1 is a portion that supplies a signal to the display panel DP. The second terminal section T2 is located closer to the display area DA than is the first terminal section T1. The second terminal section T2 is a portion that applies a voltage to the touch panel TP.

The bending portion B is provided between the terminal section T (strictly, the second terminal section T2) in the frame area FA and the display area DA. The bending portion B is a portion that is bent around a bending axis that extends in a first direction X that is a lateral direction in FIG. 1. The bending portion B extends laterally across the entire frame area DA in the first direction X. In the bending portion B, a slit SL is formed in a TFT layer 20 (detailed later).

The slit SL is provided like a groove that passes all the way through the TFT layer 20 (specifically, a stack body including a base coat film 22, a gate insulating film 32, a first interlayer insulating film 34a, and a second interlayer insulating film 34b) in the direction in which the bending portion B is extended so as to expose a substrate layer 10. In the slit SL is there provided an injection layer FL. The slit SL is filled with the injection layer FL. The injection layer FL is formed by an organic resin material such as a polyimide resin, an acrylic resin, or a polysiloxane.

The frame area FA of the organic EL display device 1 is bent by, for example, 180° (into a U-shape) at the bending portion B. Hence, both the first terminal section Tl and the second terminal section T2 are disposed on the backside of the organic EL display device 1 (indicated by a dash-double-dot line in FIG. 2). The first terminal section Tl and the second terminal section T2 are connected to a wiring board CB such as an FPC (flexible printed circuit).

### Display Panel

The display panel DP adopts an active matrix driving scheme. The display panel DP, which adopts an active matrix driving scheme, controls light-emission by the individual subpixels SP through thin film transistors (hereinafter, referred to as TFTs) 30 so as to produce an image display through the operation of the TFTs 30. Referring to FIG. 2, the display panel DP includes the substrate layer 10, the TFT layer 20, a light-emitting element layer 60, and a sealing film 70.

### Substrate Layer

The substrate layer 10 provides a base for the display panel DP. The substrate layer 10 is flexible. The substrate layer 10 is made of an organic resin material such as a polyimide resin, a polyamide resin, or an epoxy resin. The substrate layer 10 may have a structure in which inorganic insulating layers of, for example, silicon oxide and resin layers of these organic resin materials are stacked. A protective film (not shown) is attached to the rear face of the substrate layer 10.

### TFT Layer

The TFT layer 20 is provided between the substrate layer 10 and the light-emitting element layer 60. Referring to FIGS. 3 and 5 to 7, the TFT layer 20 includes a drive circuit DC, the plurality of TFTs 30, a plurality of capacitors 40, and various wiring lines 50. These drive circuit DC, various wiring lines 50, TFTs 30, and capacitors 40 are provided on the base coat film 22. The base coat film 22 is provided substantially across the entire surface of the substrate layer 10.

Referring to FIG. 3, the drive circuit DC is provided in portions of the sides of the frame area FA that are adjacent to the side where the terminal section T is provided (the left and right sides of the frame area FA in FIG. 3). The drive circuit DC includes a gate driver and an emission driver. The drive circuit DC is formed monolithically in the display panel DP. The drive circuit DC is disposed closer to the display area DA than is a trench 48 (detailed later).

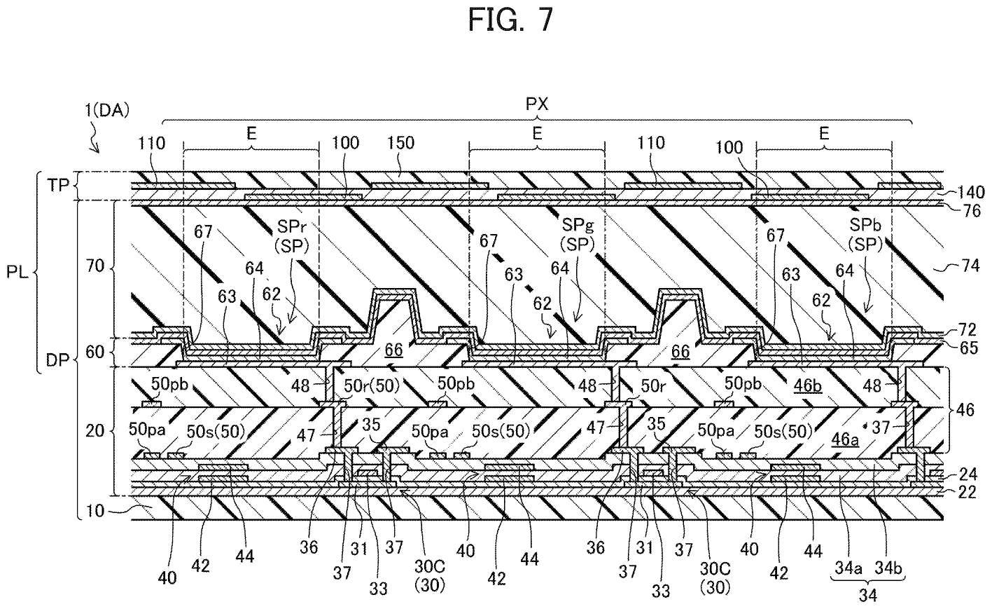

Referring to FIG. 7, each of the plurality of TFTs 30 has a top gate structure. A plurality of TFTs 30 are provided in each subpixel SP. The TFT 30 is an example of an active element. Each of the plurality of TFTs 30 includes a semiconductor layer 31, the gate insulating film 32, a gate electrode 33, an interlayer insulating film 34, a first terminal electrode 35, and a second terminal electrode 36.

The semiconductor layer 31 is provided insularly on the base coat film 22. The semiconductor layer 31 is separated individually for each TFT 30. The semiconductor layer 31 may be provided contiguously. The semiconductor layer 31 is made of, for example, a low-temperature polysilicon (LTPS). The semiconductor layer 31 may be made of an oxide semiconductor such as indium gallium zinc oxide (In—Ga—Zn—O).

The gate insulating film 32 is provided so as to cover the plurality of semiconductor layers 31. The gate insulating film 32 is formed contiguously on the base coat film 22. The gate insulating film 32 may be provided insularly on each semiconductor layer 31 and separated individually for each TFT 30. The gate electrode 33 is provided on the gate insulating film 32. The gate electrode 33 overlaps the semiconductor layer 31 via the gate insulating film 32.

The interlayer insulating film 34 includes the first interlayer insulating film 34a and the second interlayer insulating film 34b. The first interlayer insulating film 34a and the second interlayer insulating film 34b are stacked in this order on the gate insulating film 32. The interlayer insulating film 34 is provided so as to cover the plurality of gate electrodes 33. The gate insulating film 32 and the interlayer insulating film 34 have contact holes 37 formed therethrough. A pair of contact holes 37 is provided for each TFT 30.

The pair of contact holes 37 extends through the portions (conduction regions) of the semiconductor layer 31 that sandwich the region (intrinsic region) overlapping the gate electrode 33. The first terminal electrode 35 and the second terminal electrode 36 are provided on the interlayer insulating film 34. The first terminal electrode 35 and the second terminal electrode 36 are separated from each other and connected respectively to the conduction regions of the semiconductor layer 31 via the contact holes 37.

At least one of the capacitors 40 is provided for each subpixel SP. The capacitor 40 includes a first capacitor electrode 42 and a second capacitor electrode 44. The first capacitor electrode 42 is provided on the gate insulating film 32. The second capacitor electrode 44 is provided on the first interlayer insulating film 34a. The first capacitor electrode 42 and the second capacitor electrode 44 overlap each other via the first interlayer insulating film 34a.

The TFT layer 20 includes a planarization film 46. The planarization film 46 is provided so as to cover the drive circuit DC, the plurality of TFTs 30, and the plurality of capacitors 40. The surface of the TFT layer 20 is planarized by the planarization film 46. The planarization film 46 includes a first planarization film 46a and a second planarization film 46b. The first planarization film 46a and the second planarization film 46b are stacked in this order on the second interlayer insulating film 34b.

Each of the first planarization film 46a and the second planarization film 46b is made of, for example, either an organic resin material such as a polyimide resin or an acrylic resin or a polysiloxane-based SOG (spin on glass) material. The planarization film 46 spreads across the entire display area DA and on an inner circumference portion of the frame area FA. Referring to FIGS. 3, 11, and 12, the trench 48 is formed in a portion of the planarization film 46 where the frame area FA is located.

The trench 48 is formed like a frame surrounding the display area DA. The trench 48 may be formed substantially like a letter C that is open toward the terminal section in a plan view. The trench 48 extends through the planarization film 46 and separates the planarization film 46 so as to divide the planarization film 46 into the inner circumference side and the outer circumference side of the frame area FA. The trench 48 prevents the ingression of, for example, water content from the outer circumference side of the frame area FA into the display area DA.

Referring to FIGS. 3 and 7, the various wiring lines 50 include a first frame line 50fa, a second frame line 50fb, a plurality of lead lines 50h, a plurality of gate lines 50g, a plurality of source lines 50s, a plurality of emission control lines 50e, a power supply line 50p, and a plurality of relay lines 50r. The first frame line 50fa, the second frame line 50fb, and the lead lines 50h are provided in the frame area FA. The gate lines 50g, the source lines 50s, the emission control lines 50e, the power supply line 50p, and the relay lines 50r are provided in the display area DA.

Referring to FIG. 3, the first frame line 50fa is formed like a frame in the frame area FA and on the display area DA side of the drive circuit DC. The first frame line 50fa includes extension portions 50c that extend toward the first terminal section T1. One extension portion 50c is provided on each side, in terms of the first direction X, of the terminal section T ends of the first frame line 50fa. The first frame line 50fa is located on the interlayer insulating film 34. The first frame line 50fa is fed with a high-level power supply voltage (ELVDD) via the wiring board CB.

The second frame line 50fb is formed substantially like a letter C in the frame area FA so as to extend on the outer circumference side of the drive circuit DC. The second frame line 50fb have both ends thereof located on the terminal section T side of the frame area FA and extending along the extension portions 50c of the first frame line 50fa toward the first terminal section T1. The second frame line 50fb is located on the interlayer insulating film 34. The second frame line 50fb is fed with a low-level power supply voltage (ELVSS) via the wiring board CB.

The plurality of lead lines 50h are drawn out of the display area DA and extended to the first terminal section T1. The ends of the lead lines 50h located in the first terminal section T1 and the ends of the first frame line 50fa and the second frame line 50fb provide terminals. The first terminal section T1 includes a plurality of terminals. Each lead line 50h includes an underlying lead line 50hl and an overlying lead line 50hu.

The underlying lead lines 50hl are provided in a portion of the frame area FA between the display area DA and the bending portion B and in a portion of the frame area FA between the bending portion B and the first terminal section T1. The plurality of underlying lead lines 50hl are arranged at intervals from each other in the first direction X and extended parallel to each other in a second direction Y. The underlying lead lines 50hl are located on the base coat film 22. The underlying lead lines 50hl located on the display area DA side of the bending portion B are connected to the source lines 50s.

The overlying lead lines 50hu are formed on the injection layer FL so as to straddle the bending portion B. The plurality of overlying lead lines 50hu are arranged at intervals from each other in the first direction X and extended parallel to each other in the second direction Y. The overlying lead lines 50hu are located on the interlayer insulating film 34. The overlying lead lines 50hu are connected respectively to the underlying lead lines 50hl located on the display area DA side of the bending portion B and to the underlying lead lines 50hl located on the terminal section T side of the bending portion B.

A source driver is connected to each terminal of the first terminal section T1 via the wiring board CB. These terminals are connected to the wiring board CB by using an anisotropically conductive junction member such as an ACF (anisotropic conductive film). The source driver supplies a signal to the wiring lines in the display panel DP (e.g., to the source lines 50s) and to the drive circuit DC, to control image displays.

Referring to FIG. 5, the plurality of gate lines 50g are wiring lines that transfer a gate signal. The plurality of gate lines 50g are arranged at intervals from each other in the second direction Y in the display area DA and extended parallel to each other in the first direction X. One gate line 50g is provided for each row of subpixels SP. The gate lines 50g are located on the base coat film 22. The gate lines 50g are connected to a gate driver in the drive circuit DC.

The plurality of emission control lines 50e are wiring lines that transfer an emission signal. The plurality of emission control lines 50e are arranged at intervals from each other in the second direction Y and extended parallel to each other in the first direction X. One emission control line 50e is provided for each row of subpixels SP. The emission control lines 50e are located on the base coat film 22. The emission control lines 50e are connected to an emission driver in the drive circuit DC.

The plurality of source lines 50s are wiring lines that transfer a source signal. The plurality of source lines 50s are arranged at intervals from each other in the first direction X in the display area DA and extended parallel to each other in the second direction Y. One source line 50s is provided for each column of subpixels SP. The source lines 50s are located on the interlayer insulating film 34. The source lines 50s are connected to the source driver via the lead lines 50h.

The power supply line 50p is a wiring line for applying a prescribed high-level power supply voltage (ELVDD). The power supply line 50p in the present example includes a plurality of first power supply lines 50pa and a second power supply line 50pb. The plurality of first power supply lines 50pa are arranged at intervals from each other in the first direction X in the display area DA and extended parallel to each other in the second direction Y. One first power supply line 50pa is provided for each row of subpixels SP. The first power supply lines 50pa are located on the second interlayer insulating film 34b.

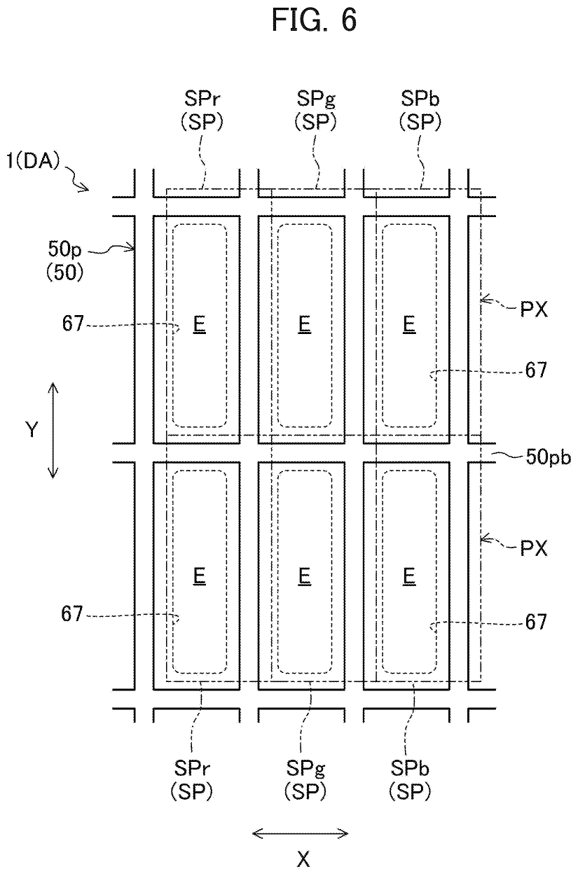

Referring to FIG. 6, the second power supply line 50pb is formed like a lattice in the first direction X and the second direction Y. The second power supply line 50pb is located on the first planarization film 46a. The second power supply line 50pb is connected mutually to each first power supply line 50pa via a contact hole (not shown) formed in the first planarization film 46a. The first power supply lines 50pa are connected to the first frame line 50fa. The first power supply lines 50pa may be located on the first interlayer insulating film 34a.

Referring to FIG. 7, the plurality of relay lines 50r are wiring lines for relaying the connection of organic EL elements 62 and the TFTs 30. One relay line 50r is provided for each subpixel SP. The relay lines 50r are formed insularly on the first planarization film 46a. The relay lines 50r are connected to the second terminal electrodes 36 of the prescribed TFTs 30 (third TFTs 30C) via contact holes 47 formed through the first planarization film 46a. Then, the relay lines 50r are connected to pixel electrodes 63 of the organic EL elements 62 via contact holes 48 formed through the second planarization film 46b.

The base coat film 22, the gate insulating film 32, the first interlayer insulating film 34a, and the second interlayer insulating film 34b are made of, for example, an inorganic insulating material such as silicon oxide, silicon nitride, or silicon oxynitride. The base coat film 22, the gate insulating film 32, the first interlayer insulating film 34a, and the second interlayer insulating film 34b are made from a monolayer film or a stacked film of inorganic insulating materials.

The gate electrodes 33, the first capacitor electrodes 42, the gate lines 50g, the emission control lines 50e, and the underlying lead lines 50hl are made of the same material and provided in the same layer. The first terminal electrodes 35, the second terminal electrodes 36, the first frame line 50fa, the second frame line 50fb, the overlying lead lines 50hu, the source lines 50s, and the first power supply lines 50pa are made of the same material and provided in the same layer. The second power supply lines 50pb and the relay lines 50r are made of the same material and provided in the same layer.

The above-described various wiring lines 50 and electrodes in the display panel DP are made of a metal material such as aluminum (Al), tungsten (W), molybdenum (Mo), tantalum (Ta), chromium (Cr), titanium (Ti), or copper (Cu). Each of these various wiring lines 50 and electrodes includes a monolayer film or a stacked film of the metal materials.

### Light-Emitting Element Layer

Referring to FIG. 7, the light-emitting element layer 60 is provided on the TFT layer 20 and includes the plurality of organic EL elements (organic electroluminescence elements) 62. The organic EL elements 62 are an example of light-emitting elements. The organic EL elements 62 have a top-emission structure. In the top-emission organic EL elements 62, the light emitted by an organic EL layer 64 is taken out through the sealing film 70 side. Each organic EL element 62 includes a pixel electrode 63, the organic EL layer 64, and a common electrode 65.

The pixel electrode 63 is provided in each subpixel SP. The pixel electrode 63 is arranged in a matrix correspondingly to the subpixels SP. The pixel electrode 63 is provided on the planarization film 46. The pixel electrode 63 is reflective to light. The pixel electrode 63 functions as an anode. The pixel electrode 63 is preferably made of a conductive material that has a large work function.

The light-emitting element layer 60 includes an edge cover 66 together with the plurality of pixel electrodes 63. The edge cover 66 is provided on the planarization film 46 so as to separate the plurality of pixel electrodes 63. The edge cover 66 is formed like a lattice to cover the peripheral portion of each pixel electrode 63. The edge cover 66 is made of, for example, either an organic resin material such as a polyimide resin or an acrylic resin or a polysiloxane-based SOG material. The regions of the edge cover 66 that correspond to the openings 67 form the light-emitting regions E.

The organic EL layer 64 is provided on each pixel electrode 63 in the openings 67 of the edge cover 66. The organic EL layer 64 includes a hole injection layer, a hole transport layer, a light-emitting layer, an electron transport layer, and an electron injection layer, all provided sequentially on the pixel electrode 63. The hole injection layer, the hole transport layer, the light-emitting layer, the electron transport layer, and the electron injection layer are each made of a publicly known compound suited to its function. The organic EL layer 64 emits light when a current is applied across the pixel electrode 63 and the common electrode 65.

The common electrode 65 is contiguously provided commonly to the plurality of subpixels SP. The common electrode 65 is disposed on the organic EL layers 64, covering the edge cover 66, and overlaps the pixel electrodes 63 via the organic EL layers 64. The common electrode 65 is transmissive to light. The common electrode 65 functions as a cathode. The common electrode 65 is preferably made of a conductive material that has a small work function.

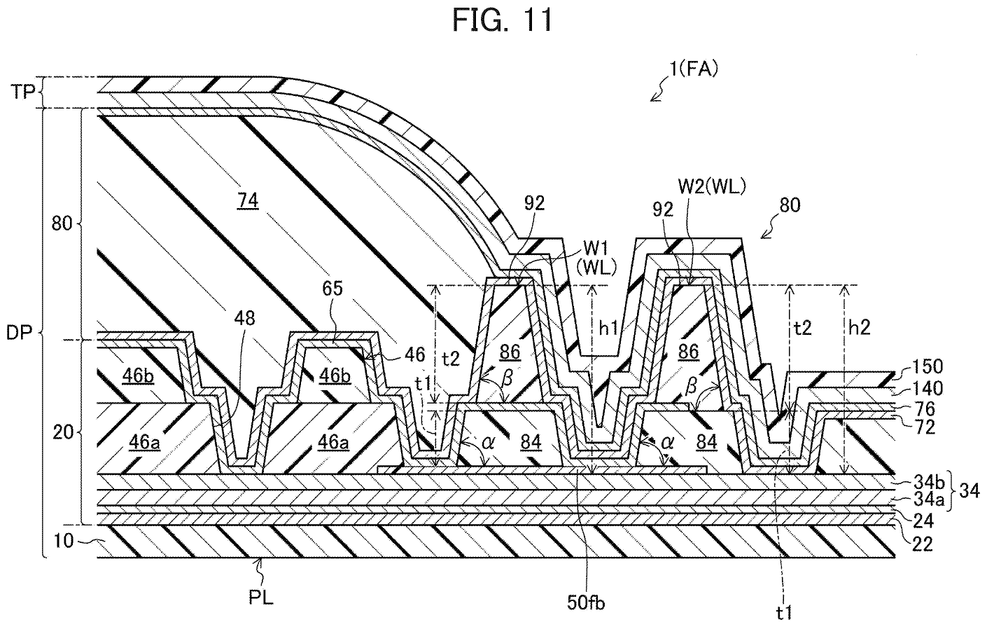

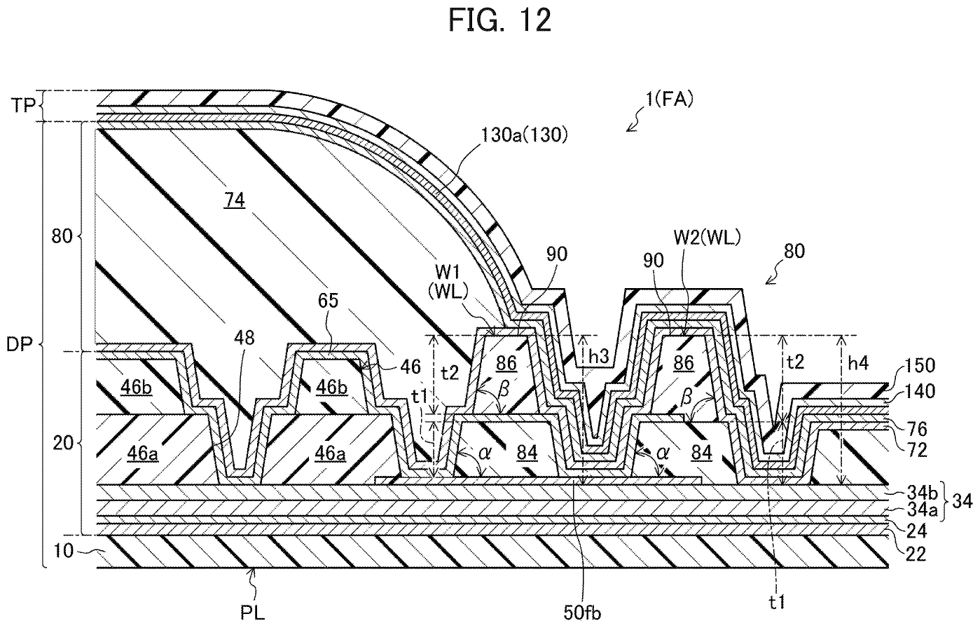

The common electrode 65 spreads reaching the frame area FA and is connected to the second frame line 50fb (see FIGS. 11 and 12).

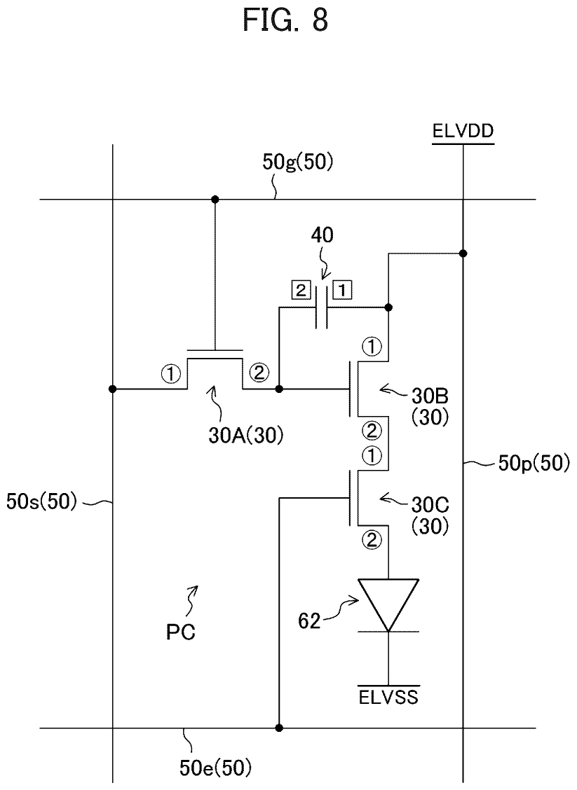

The TFT 30, the capacitor 40, and the organic EL element 62 in each subpixel SP form a pixel circuit PC such as the one shown in FIG. 8. The pixel circuit PC controls the emission of light by the organic EL element 62 on the basis of a gate signal supplied to the gate line 50g, an emission signal supplied to the emission control line 50e, a source signal supplied to the source line 50s, the high-level power supply voltage (ELVDD) supplied to the power supply line 50p, and the low-level power supply voltage (ELVSS) supplied to the common electrode 65.

The equivalent circuit diagram in FIG. 8 denotes the first terminal electrode 35 of the TFT 30 by a circled number 1 and the second terminal electrode 36 of the TFT 30 by a circled number 2. The diagram also denotes the first capacitor electrode 42 of the capacitor 40 by a squared number 1 and the second capacitor electrode 44 of the capacitor 40 by a squared number 2. The plurality of TFTs 30 in the pixel circuit PC in accordance with the present example are a first TFT 30A, a second TFT 30B, and the third TFT 30C.

In the first TFT 30A, the gate electrode 33 is connected to a corresponding one of the gate lines 50g, the first terminal electrode 35 is connected to a corresponding one of the source lines 50s, and the second terminal electrode 36 is connected to a corresponding one of the second TFTs 30B. In the second TFT 30B, the gate electrode 33 is connected to the second terminal electrode 36 of a corresponding one of the first TFTs 30A, the first terminal electrode 35 is connected to a corresponding one of the power supply lines 50p, and the second terminal electrode 36 is connected to a corresponding one of the third TFTs 30C.

In the third TFT 30C, the gate electrode 33 is connected to a corresponding one of the emission control lines 50e, the first terminal electrode 35 is connected to the second terminal electrode 36 of a corresponding one of the second TFTs 30B, and the second terminal electrode 36 is connected to the pixel electrode 63 of a corresponding one of the organic EL elements 62. In the capacitor 40, the first capacitor electrode 42 is connected to the power supply line 50p, and the second capacitor electrode 44 is connected to the second terminal electrode 36 of the first TFT 30A and the gate electrode 33 of the second TFT 30B.

### Sealing Film

Referring to FIG. 7, the sealing film 70 is provided on the light-emitting element layer 60. The sealing film 70 covers the plurality of organic EL elements 62 to protect the organic EL elements 62 (particularly, the organic EL layers 64) from, for example, water content and oxygen. The sealing film 70 has, for example, a TFE (thin film encapsulation) structure. Such a sealing film 70 includes a first inorganic layer 72, an organic layer 74, and a second inorganic layer 76. The first inorganic layer 72, the organic layer 74, and the second inorganic layer 76 are provided in this order on the light-emitting element layer 60 and spread on the display area DA.

The first inorganic layer 72 and the second inorganic layer 76 are each made of, for example, an inorganic insulating material such as silicon oxide, silicon nitride, or silicon oxynitride. The organic layer 74 is an example of a coating film. In other words, the coating film in accordance with the present example is included in the sealing film 70. The organic layer 74 is made of, for example, an organic resin material such as an acrylic resin, an epoxy resin, a silicone resin, a polyurea resin, a parylene resin, a polyimide resin, or a polyamide resin.

### Touch Panel

Referring to FIG. 2, the touch panel TP is provided on the display panel DP. In other words, the touch panel TP is provided in an overlying layer of the organic layer 74 which is a coating film. The touch panel TP is an on-cell touch panel. The touch panel TP adopts a projected capacitive scheme. Referring to FIGS. 4 and 7, the touch panel TP includes a plurality of first detection electrodes 100, a plurality of second detection electrodes 110, a plurality of touch panel lines 130, an interlayer insulating film 140, and an overcoat film 150.

The plurality of first detection electrodes 100 are arranged in a matrix in the touch area TA. The plurality of second detection electrodes 110 are also arranged in a matrix in the touch area TA. Both the first detection electrodes 100 and the second detection electrodes 110 are electrodes used in detecting a touch position. The first detection electrodes 100 and the second detection electrodes 110 are arranged alternately and next to each other in an oblique direction with respect to the first direction X and the second direction Y.

Each first detection electrode 100 is formed like, for example, a rhombus. The first detection electrodes 100 that are adjacent to each other in the first direction X have corners facing each other. The first detection electrodes 100 that are adjacent to each other in the second direction Y also have corners facing each other. The corners of the first detection electrodes 100 that are adjacent to each other in the first direction X are coupled to each other via a first coupling line 102. The plurality of first detection electrodes 100 that are arranged next to each other in the first direction X form a first electrode group 104.

Each second detection electrode 110 is formed like, for example, a rhombus. The second detection electrodes 110 that are adjacent to each other in the first direction X have corners facing each other. The second detection electrodes 110 that are adjacent to each other in the second direction Y also have corners facing each other. The corners of the second detection electrodes 110 that are adjacent to each other in the second direction X are coupled to each other via a second coupling line 112. The plurality of second detection electrodes 110 that are arranged next to each other in the second direction Y form a second electrode group 114.

The plurality of touch panel lines 130 are provided in the frame area FA. The touch panel lines 130 are wiring lines in the touch panel TP. In the touch panel TP, the touch panel lines 130 are drawn out of the touch area TA and extended to the second terminal section T2. The ends, of the touch panel lines 130, that are located in the second terminal section T2 provide terminals. The second terminal section T2 includes a plurality of terminals. The touch panel lines 130 include a plurality of first touch panel lines 130a and a plurality of second touch panel lines 130b.

One first touch panel line 130a is provided for each first electrode group 104. Each first touch panel line 130a is connected to the first detection electrode 100 located at an end of the first electrode group 104. Each first touch panel line 130a is routed from the touch area TA to the second terminal section T2 through a portion that forms either one of the sides of the frame area FA with respect to the first direction X (either the left or right side in the example shown in FIG. 4).

The first touch panel lines 130a connected to the adjacent, first electrode groups 104 are drawn out to different sides of the frame area FA. The first touch panel lines 130a located in a portion of the same side of the frame area FA are provided so as to extend parallel to each other, separated by a distance from each other, and straddle the bending portion B. The first touch panel lines 130a may be routed to the second terminal section T2 only through a portion that forms one of the sides of the frame area FA with respect to the first direction X.

One second touch panel line 130b is provided for each second electrode group 114. Each second touch panel line 130b is connected to the second detection electrode 110 located at an end of the second electrode group 114. The portions of the second touch panel lines 130b that are a part of a side of the frame area FA that is located on the terminal section T side of the frame area FA are drawn out to the second terminal section T2. The plurality of second touch panel lines 130b are provided so as to extend parallel to each other, separated by a distance from each other, and straddle the bending portion B.

A touch detection circuit (not shown) is connected to each terminal of the second terminal section T2 via the wiring board CB. These terminals are connected to the wiring board CB by using an anisotropically conductive junction member such as an ACF. The touch detection circuit detects changes in the electrostatic capacity produced between the contact body and the first detection electrodes 100 and the second detection electrodes 110 contained in the touch panel TP when the touch area TA is touched by the contact body.

The plurality of first detection electrodes 100, the plurality of first coupling lines 102, and the plurality of first touch panel lines 130a are provided on the sealing film 70. The first detection electrodes 100, the first coupling line 102, and the first touch panel lines 130a are made of the same material and provided in the same layer. The interlayer insulating film 140 is provided so as to cover the plurality of first detection electrodes 100, the plurality of first coupling lines 102, and the plurality of first touch panel lines 130a.

The interlayer insulating film 140 is made of an inorganic insulating material similarly to, for example, the first interlayer insulating film 34a in the TFT layer 20. The interlayer insulating film 140 includes a monolayer film or a stacked film of an inorganic insulating material. The plurality of second detection electrodes 110, the plurality of second coupling lines 112, and the plurality of second touch panel lines 130b are provided on the interlayer insulating film 140. The second detection electrodes 110, the second coupling line 112, and the second touch panel lines 130b are made of the same material and provided in the same layer.

The above-described various wiring lines and electrodes in the touch panel TP are made of an electrically conductive oxide that is transmissive to light. Examples of such an electrically conductive oxide include indium tin oxide (ITO) and indium zinc oxide (IZO). Each of these wiring lines and electrodes includes a monolayer film or a stacked film of the electrically conductive oxides. The first touch panel lines 130a and the second touch panel lines 130b may be made of a metal material similarly to the various wiring lines and electrodes in the display panel DP.

In the touch area TA, the overcoat film 150 is provided so as to cover the plurality of second detection electrodes 110 and the plurality of second coupling lines 112. The overcoat film 150 is provided in the frame area FA so as to, in portions except for the second terminal section T2, cover the first touch panel lines 130a via the interlayer insulating film 140 and directly cover the second touch panel lines 130b. The overcoat film 150 is made of, for example, an organic resin material, such as an acrylic resin, that is transmissive to light.

### Damming Portion

As shown in FIGS. 3, 9, and 10, a damming portion 80 is provided in the frame area FA of the organic EL display device 1. The damming portion 80, when a liquid organic resin material that will form the organic layer 74 in the sealing film 70 is applied in the manufacturing of the organic EL display device 1, serves to dam up and hence prevents the organic resin material from spreading to the outside of the frame area FA. The damming portion 80 includes a plurality of damming walls WL. The damming walls WL in accordance with the present example include a first damming wall W1 and a second damming wall W2.

The first damming wall W1 is an example of a first wall body (wall body). The second damming wall W2 is an example of a second wall body (wall body). The first damming wall W1 is shaped like a frame along the outer circumference of the planarization film 46. The first damming wall W1 is disposed at a distance from the planarization film 46. The second damming wall W2 is shaped like a frame along the outer circumference of the first damming wall W1. The first damming wall W1 and the second damming wall W2 are disposed at a distance in the width direction of the frame area FA from each other. The first damming wall W1 and the second damming wall W2 function as banks for damming up the organic resin material in forming the organic layer 74.

Referring to FIGS. 11 to 13, the first damming wall W1 and the second damming wall W2 each include a first wall layer 84 and a second wall layer 86. The first wall layer 84 is provided on the interlayer insulating film 34. The first wall layer 84 is supported by the substrate layer 10 via the base coat film 22, the gate insulating film 32, and the interlayer insulating film 34. The first wall layer 84 in accordance with the present example is made of the same material, and provided in the same layer, as the second planarization film 46b. The second wall layer 86 is provided on the first wall layer 84. The second wall layer 86 in accordance with the present example is made of the same material, and provided in the same layer, as the edge cover 66.

The second frame line 50fb extends in an underlying layer of the first damming wall W1 and the second damming wall W2. The common electrode 65 is provided so as to cover the inner face of the trench 48, intervene between the first wall layer 84 and the second wall layer 86 in the first damming wall W1, and overlap an inner circumference portion of the first wall layer 84 in the second damming wall W2. Then, the common electrode 65 is connected to the second frame line 50fb between the planarization film 46 and the first damming wall W1 and between the first damming wall W1 and the second damming wall W2.

The first inorganic layer 72 in the sealing film 70 covers the first damming wall W1 and the second damming wall W2 and extends to the outer circumference side of the second damming wall W2. The organic layer 74 is provided to the internal side of the first damming wall W1 and the second damming wall W2 on the first inorganic layer 72. The organic layer 74 may be present between the first damming wall W1 and the second damming wall W2. The second inorganic layer 76 covers the organic layer 74 and extends to the outer circumference side of the second damming wall W2. The organic layer 74 is wrapped up by the first inorganic layer 72 and the second inorganic layer 76 and enclosed between these layers 72 and 76.

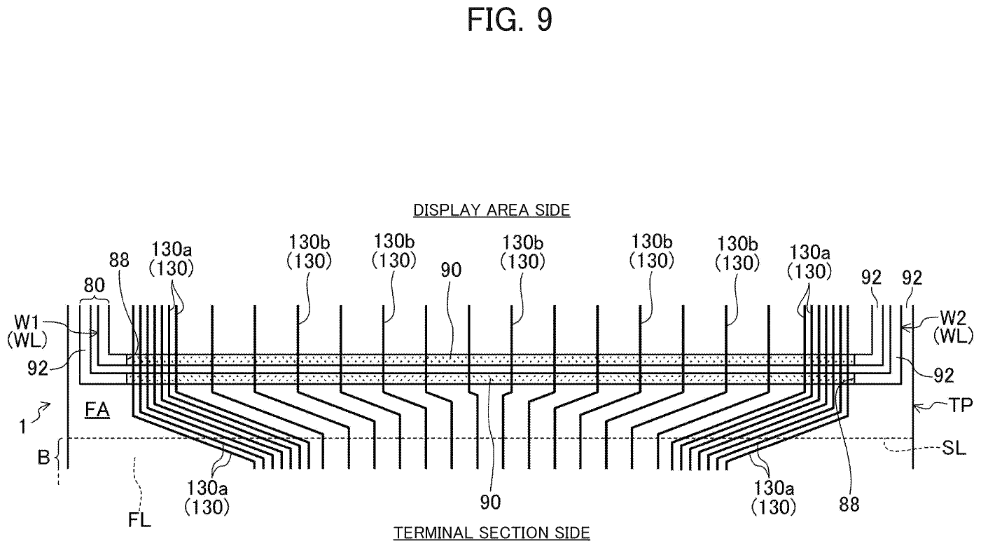

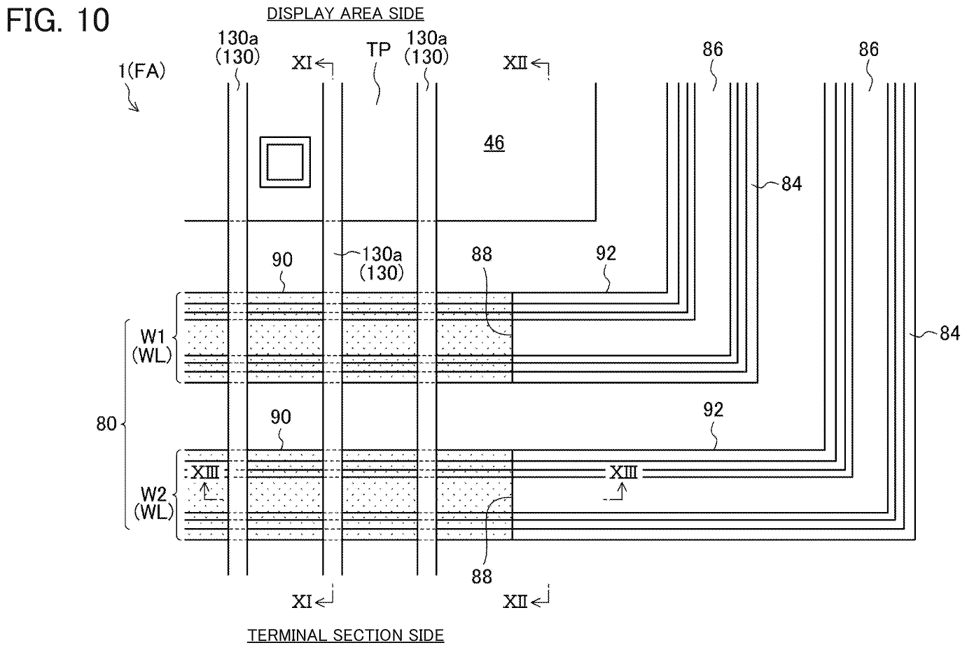

Referring to FIGS. 9 and 10, the touch panel lines 130 cross the first damming wall W1 and the second damming wall W2 on the terminal section T side of the frame area FA. The touch panel lines 130 extend from the display area DA side to the outside of the frame area FA so as to straddle the first damming wall W1 and the second damming wall W2 (FIG. 12 shows an example of the first touch panel lines 130a). The plurality of touch panel lines 130 extend parallel to each other on the first damming wall W1 and the second damming wall W2.

The first damming wall W1 and the second damming wall W2 have recesses 88 provided therein. The recesses 88 are provided contiguously across the portions of the first damming wall W1 and the second damming wall W2 where the plurality of touch panel lines 130 extend. Low wall portions 90 of the first damming wall W1 and the second damming wall W2 that correspond to the recesses 88 (indicated by dot-hatching in FIGS. 9 and 10) are lower in height than ordinary wall portions 92 that are portions of the first damming wall W1 and the second damming wall W2 other than the low wall portions 90.

Referring to FIG. 11, the height h1 of the ordinary wall portion 92 of the first damming wall W1 is equivalent to the height h2 of the ordinary wall portion 92 of the second damming wall W2. The thickness t1 of the first wall layer 84 in the ordinary wall portion 92 of the first damming wall W1 is equivalent to the thickness t1 of the first wall layer 84 in the ordinary wall portion 92 of the second damming wall W2. The thickness t2 of the second wall layer 86 in the ordinary wall portion 92 of the first damming wall W1 is equivalent to the thickness t2 of the second wall layer 86 in the ordinary wall portion 92 of the second damming wall W2.

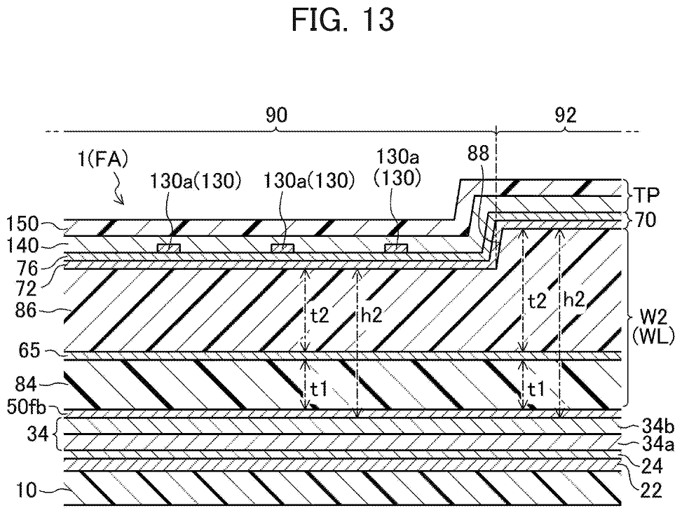

Referring to FIG. 12, the height h3 of the low wall portion 90 of the first damming wall W1 is equivalent to the height h4 of the low wall portion 90 of the second damming wall W2. In the first damming wall W1 and the second damming wall W2 in accordance with the present example, the thickness t1 of the first wall layer 84 in the low wall portion 90 is equivalent to the thickness t1 of the first wall layer 84 in the ordinary wall portion 92, whereas the thickness t2 of the second wall layer 86 in the low wall portion 90 differs from the thickness t2 of the second wall layer 86 in the ordinary wall portion 92 (FIG. 13 shows an example of the second damming wall W2). In each of the first damming wall W1 and the second damming wall W2, the thickness t2 of the second wall layer 86 in the low wall portions 90 is smaller than the thickness t2 of the second wall layer 86 in the ordinary wall portion 92.

The side faces of the first damming wall W1 and the second damming wall W2 make angles α and β of, for example, approximately from 30° to 50° with the respective formation faces of the first wall layer 84 and the second wall layer 86. In the first damming wall W1 and the second damming wall W2, the heights h3 and h4 of the low wall portion 90 are set to approximately 60% to 66% the heights h1 and h2 of the ordinary wall portion 92. For example, the heights h1 and h2 of the ordinary wall portions 92 of the first damming wall W1 and the second damming wall W2 are approximately from 5.0 μm to 6.0 μm. In such a case, the heights h3 and h4 of the low wall portions 90 of the first damming wall W1 and the second damming wall W2 are, for example, approximately from 3.0 μm to 4.0 μm.

### Operation of Organic EL Display Device

In each subpixel SP in the organic EL display device 1, first, the corresponding one of the emission control lines 50e is selected and deactivated, which turns the organic EL element 62 into a non-emissive state. Then, one of the gate lines 50g that corresponds to the organic EL element 62 in non-emissive state is selected and activated, which allows a gate signal to be fed to the first TFT 30A via that one of the gate lines 50g and hence turns on the first TFT 30A.

As the first TFT 30A is turned on, a prescribed voltage corresponding to the source signal transferred via the source line 50s is applied to the second TFT 30B and also written to the capacitor 40. Then, as the emission control line 50e is deselected and hence activated, an emission signal is fed to the third TFT 30C via that emission control line 50e, which turns on the third TFT 30C.

As the third TFT 30C is turned on, a current is fed from the power supply line 50p to the organic EL element 62 in accordance with the gate voltage of the second TFT 30B. Hence, the organic EL layer 64 (light-emitting layer) emits light in each subpixel SP. As a result, an image is displayed. Note that the emission of light by the organic EL layer 64 is maintained in each subpixel SP until a gate signal is fed in a next frame because the gate voltage of the second TFT 30B is retained by the capacitor 40 even when the first TFT 30A is turned off.

### Method of Manufacturing Organic EL Display Device

To manufacture the organic EL display device 1, first, the substrate layer 10 is formed by applying an organic resin material to the surface of a glass substrate 500 and subjecting the glass substrate 500 to, for example, a baking process. Next, a display panel SP (the TFT layer 20, the light-emitting element layer 60, and the sealing film 70) and the touch panel TP are fabricated sequentially on the substrate layer 10 by a publicly known technique such as photolithography, vacuum vapor deposition, spin-coating, or inkjet printing technology.

Then, the panel body PL is fabricated on the glass substrate 500. Next, the glass substrate 500 is lifted off the substrate layer 10 by, for example, projecting a laser beam onto the rear face of the substrate layer 10 from the glass substrate side. Subsequently, a polarizer and a cover panel are attached sequentially on the front face of the panel body PL. In addition, a protective film is attached onto the rear face of the substrate layer 10. Thereafter, the source driver and the touch detection circuit are mounted by connecting the wiring board CB to the first terminal section T1 and the second terminal section T2 of the panel body PL.

The organic EL display device 1 is manufactured in this manner.

In a step of forming the TFT layer 20, a photosensitive resin material is applied onto the substrate by, for example, a publicly known printing or coating technique such as spin-coating, the substrate carrying formed thereon the first terminal electrodes 35, the second terminal electrodes 36, the first frame line 50fa, the second frame line 50fb, the overlying lead lines 50h, the source lines 50s, and the first power supply lines 50pa. Next, the first planarization film 46a and the first wall layer 84 are formed by subjecting the coating film of the photosensitive resin material to pre-baking, exposure to light, development, and post-baking to pattern this coating film.

Thereafter, a photosensitive resin material is applied onto the substrate on which the second power supply line 50pb and the relay lines 50r are provided, by, for example, a publicly known printing or coating technique such as spin-coating. Next, the edge cover 66 and the second wall layer 86 are formed by subjecting the coating film of the photosensitive resin material to pre-baking, exposure to light, development, and post-baking to pattern this coating film.

In so doing, the second wall layer 86 in the first damming wall W1 and the second wall layer 86 in the second damming wall W2 are rendered to have different surface heights by using, for example, a gray tone mask or a halftone mask in exposing the coating film of the photosensitive resin material, thereby forming the recesses 88 in the second wall layer 86 in the first damming wall W1 and in the second wall layer 86 in the second damming wall W2. Hence, the low wall portions 90 and the ordinary wall portions 92 are formed by providing the recesses 88 in the first damming wall W1 and the second damming wall W2 at the same time as the formation of the first damming wall W1 and the second damming wall W2.

The provision of the first damming wall W1 and the second damming wall W2, which have the recesses 88 as described here, restrains the first touch panel lines 130a and the second touch panel lines 130b from breaking on the first damming wall W1 and the second damming wall W2 when the first touch panel lines 130a and the second touch panel lines 130b are formed in the manufacturing of the touch panel TP. The first touch panel lines 130a and the second touch panel lines 130b are formed by common technology. The following will give a description by taking, as an example, a step of forming the first touch panel lines 130a.

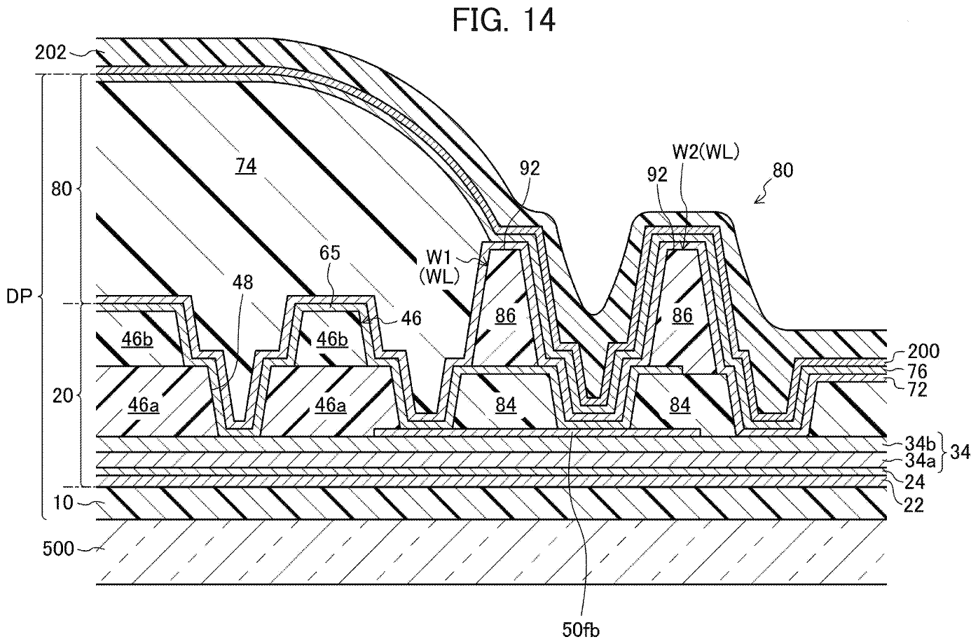

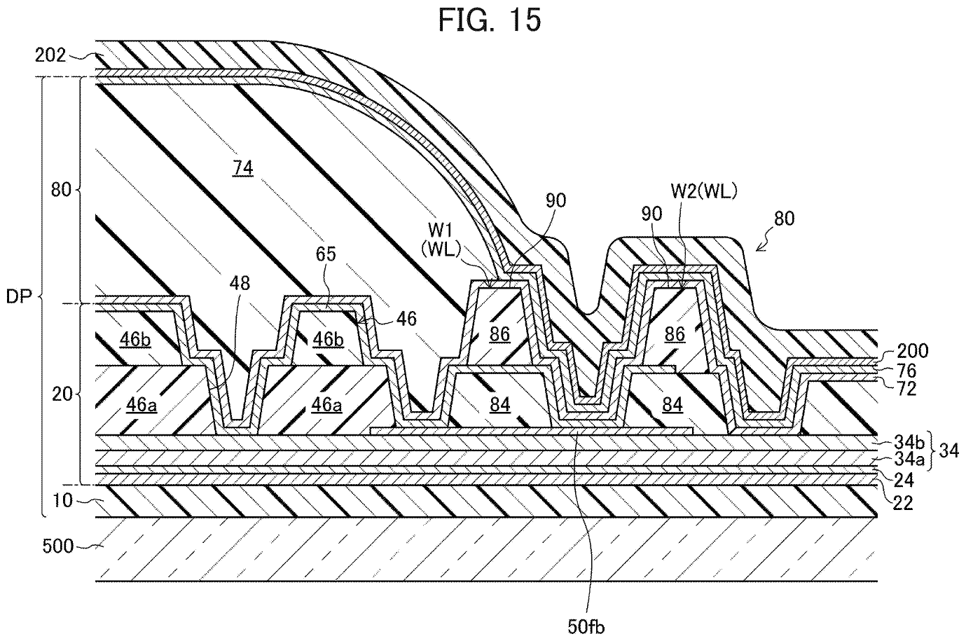

In the step of forming the first touch panel lines 130a, first, an electrically conductive transparent film 200 of, for example, indium tin oxide (ITO) is formed by, for example, sputtering on the substrate on which the sealing film 70 is provided. Next, referring to FIGS. 14 to 16, a resist 202 is applied onto the substrate on which the electrically conductive transparent film 200 is provided, by a publicly known printing or coating technique such as spin-coating.

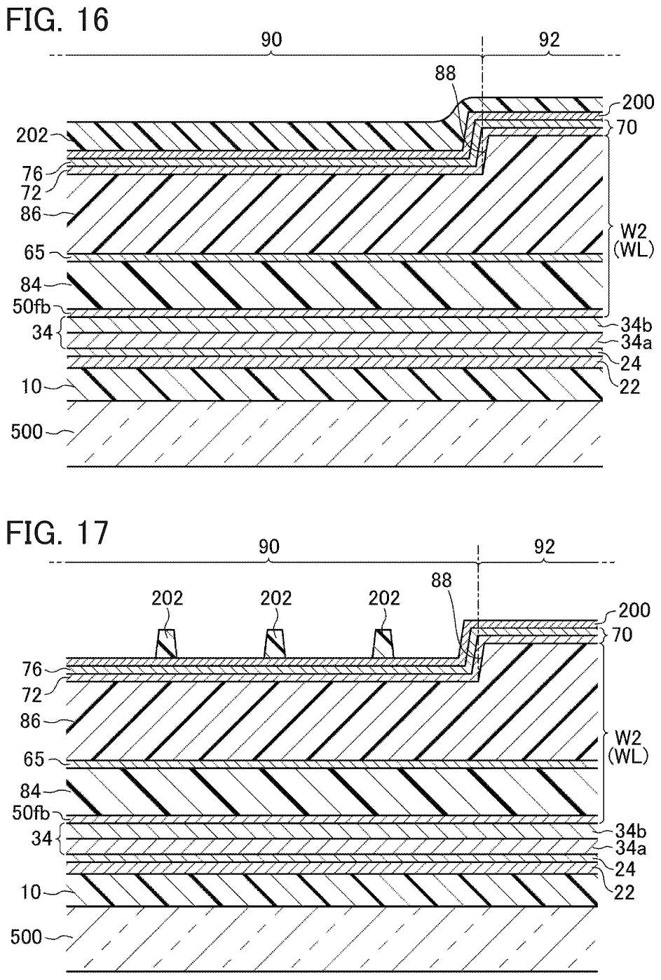

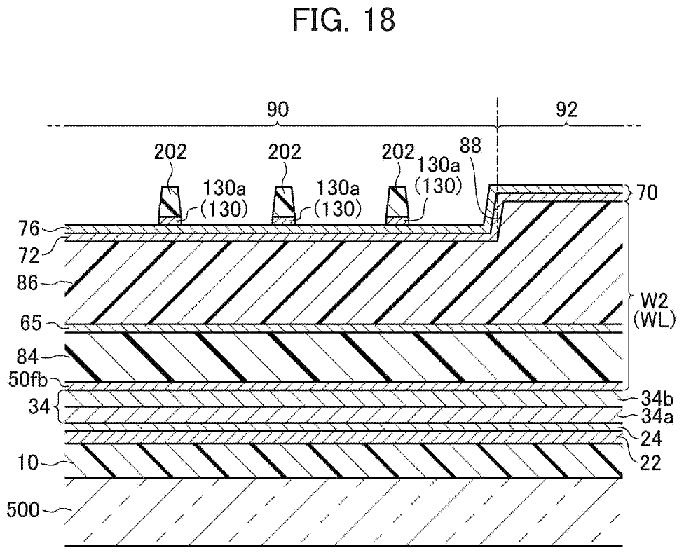

Subsequently, the resist 202 is patterned in regions including the recesses 88 (regions where the first detection electrodes 100, the first coupling lines 102, and the first touch panel lines 130a are formed) by subjecting the coating film of the resist 202 to pre-baking, exposure to light, development, and post-baking as shown in FIG. 17. Then, as shown in FIG. 18, the first touch panel lines 130a are formed as well as the first detection electrodes 100 and the first coupling lines 102, by patterning the electrically conductive transparent film 200 through etching using the resist 202 as a mask. Thereafter, the resist 202 is removed by, for example, ashing.

In so doing, if the first damming wall W1 and the second damming wall W2 have no recesses 88, the first touch panel lines 130a could easily break.

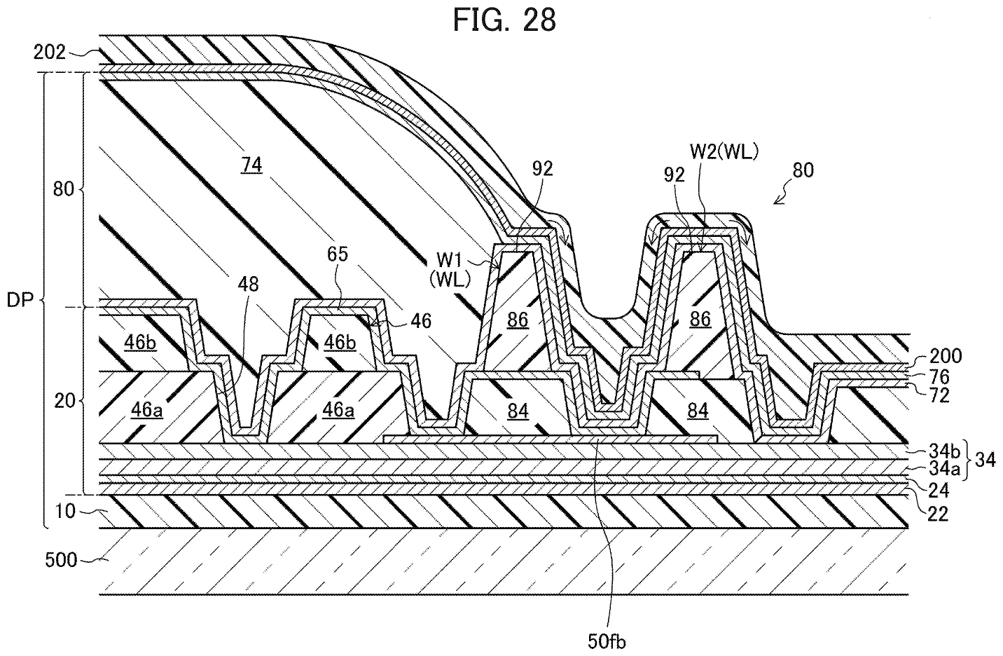

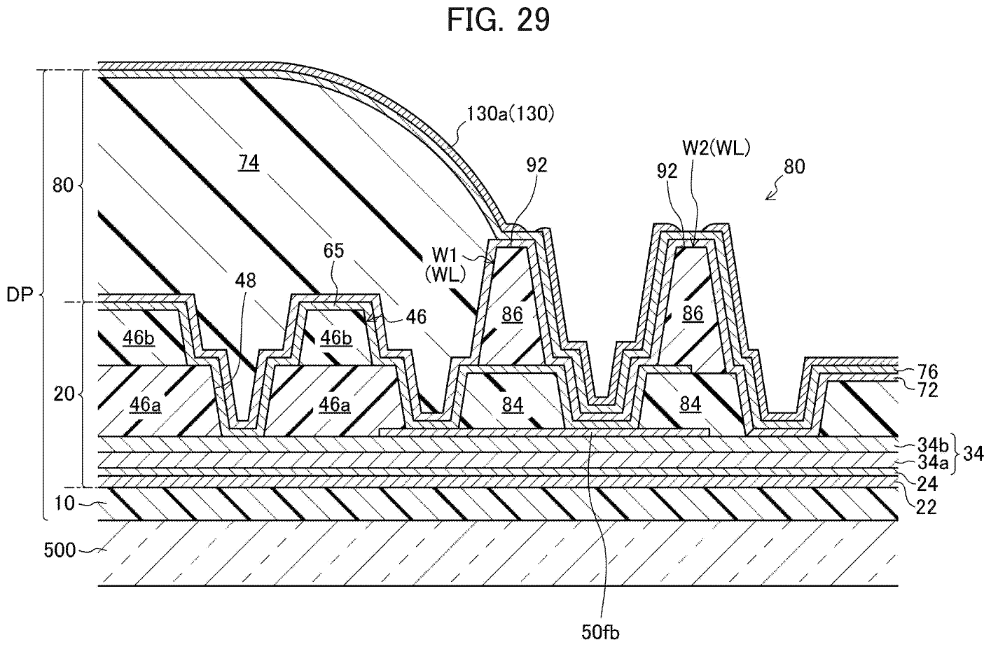

The first damming wall W1 and the second damming wall W2 are designed to be relatively high for the purpose of damming up, and hence preventing from spreading outside the frame area FA, the organic resin material that will form the organic layer 74. When the first damming wall W1 and the second damming wall W2 are higher, the resist 202 will more likely flow from the top portions of the first damming wall W1 and the second damming wall W2 to both sides and fail to cover the top portions of the first damming wall W1 and the second damming wall W2 in a suitable manner as shown in FIG. 28. Then, the electrically conductive transparent film 200 could be etched in those portions where the first touch panel lines 130a are formed on the first damming wall W1 and the second damming wall W2 when the first touch panel lines 130a are patterned. As a result, referring to FIG. 29, the first touch panel lines 130a would be missing, causing breaks in the first touch panel lines 130a. Similar problems can occur with the second touch panel lines 130b.

In contrast, in the organic EL display device 1 in accordance with the present example, the recesses 88 are provided in the portions of the first damming wall W1 and the second damming wall W2 where the first touch panel lines 130a and the second touch panel lines 130b extend, and those portions provide the low wall portions 90 which are relatively low in height.

Hence, the resist 202, used as a mask in forming the first touch panel lines 130a and the second touch panel lines 130b, can be restrained from flowing from the top portions of the first damming wall W1 and the second damming wall W2 to both sides. Hence, the resist 202 can be provided so as to suitably cover the top portion of the first damming wall W1 and top portion of the second damming wall W2 with the low wall portion 90, and those portions of the electrically conductive transparent film 200 where the first touch panel lines 130a and the second touch panel lines 130b are formed can be restrained from being etched. Therefore, the first touch panel lines 130a and the second touch panel lines 130b can be restrained from breaking up on the first damming wall W1 and the second damming wall W2.

### Features of Embodiment

In the organic EL display device 1 in accordance with the present embodiment, the first damming wall W1 and the second damming wall W2 have the respective recesses 88, and the portions of the first damming wall W1 and the second damming wall W2 where the touch panel lines 130 extend are lower in height than the other portions thereof. This feature can restrain breaking of the touch panel lines 130 on the first damming wall W1 and the second damming wall W2 when the touch panel lines 130 are formed.

In the organic EL display device 1 in accordance with the present embodiment, the recesses 88 are provided contiguously across the portions of the first damming wall W1 and the second damming wall W2 where the plurality of touch panel lines 130 extend. This feature can alleviate the precision required for the locations and dimensions of the recesses 88, when compared with cases where a plurality of recesses 88 are provided separately for each touch panel line 130. It is hence easy for the first damming wall W1 and the second damming wall W2 to have a structure in which the touch panel lines 130 are unlikely to break in patterning.

In the organic EL display device 1 in accordance with the present embodiment, the recesses 88 are provided respectively in the first damming wall W1 and the second damming wall W2. This feature can restrain the touch panel lines 130 from breaking on both the first damming wall W1 and the second damming wall W2. This feature is advantageous in improving the yield of the organic EL display device 1.

In the organic EL display device 1 in accordance with the present embodiment, the first damming wall W1 and the second damming wall W2 include the first wall layer 84 and the second wall layer 86 respectively. Then, the portions of the second wall layer 86 that correspond to the recesses 88 are thinner than the other portions of the second wall layer 86. This feature enables providing the recesses 88 in the first damming wall W1 and the second damming wall W2 without having to increase the number of wall layers in the first damming wall W1 and the second damming wall W2. This feature is advantageous in increasing the productivity of the organic EL display device 1 and cutting the cost of the organic EL display device 1.

In the organic EL display device 1 in accordance with the present embodiment, the organic EL elements 62 are used as light-emitting elements. The organic EL elements 62 are susceptible to degradation as they react with, for example, water content and oxygen and are therefore covered, and hence sealed, with the sealing film 70. The sealing film 70 in accordance with the present example has a TFE structure and contains the organic layer 74. Then, the first damming wall W1 and the second damming wall W2 are both wall bodies for damming up an organic liquid resin material when the organic layer 74 is formed as a coating film.

In the sealing film 70, the organic layer 74 is much thicker than the first inorganic layer 72 and the second inorganic layer 76 for the purpose of serving to increase flexibility and alleviate stress. Therefore, the first damming wall W1 and the second damming wall W2 are designed to be relatively high to render more reliable the function of damming up the organic liquid resin material that forms the organic layer 74. The technique of the present disclosure is effective in restraining breaking of the touch panel lines 130 on the first damming wall W1 and the second damming wall W2 designed in this manner.

In the organic EL display device 1 in accordance with the present embodiment, the first wall layer 84 is made of the same material, and provided in the same layer, as the second planarization film 46b. In addition, the second wall layer 86 is made of the same material, and provided in the same layer, as the edge cover 66. These features enable the first wall layer 84 to be made in the same process as the second planarization film 46b and the second wall layer 86 to be made in the same process as the edge cover 66, in the manufacturing of the organic EL display device 1. Therefore, the first wall layer 84 and the second wall layer 86 do not need to be formed in different, independent processes than the other structural elements.

### First Variation Example

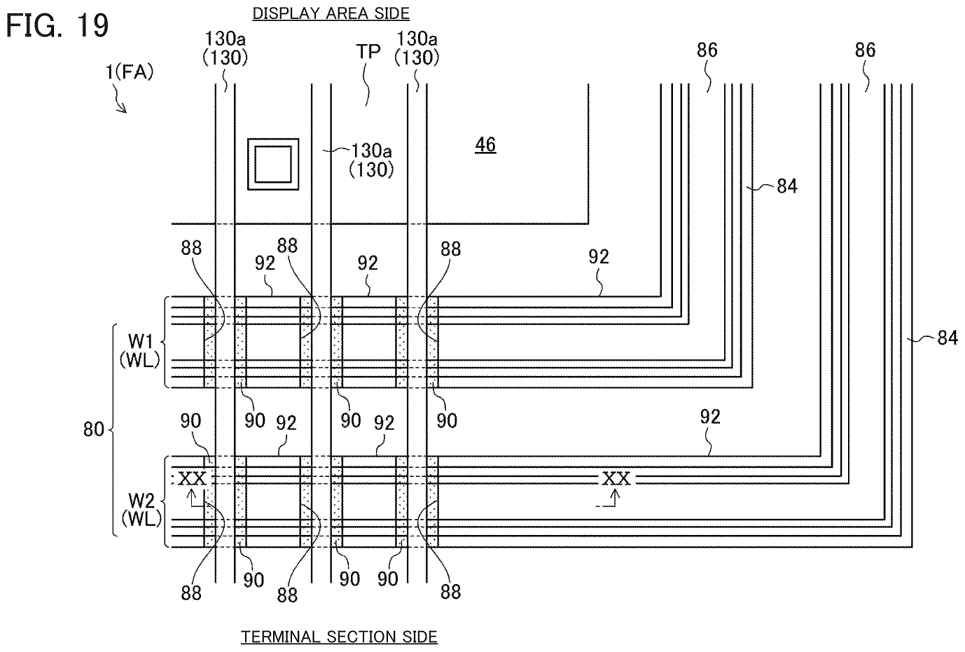

Referring to FIG. 19, in the organic EL display device 1 in accordance with this first variation example, the damming portion 80 includes the first damming wall W1 and the second damming wall W2. The recesses 88 in accordance with the present example are also provided in the first damming wall W1 and the second damming wall W2 respectively. Then, a plurality of recesses 88 are provided separately for each touch panel line 130 in the first damming wall W1 and the second damming wall W2. The recesses 88 in the first damming wall W1 and the recesses 88 in the second damming wall W2 are provided in mutually corresponding locations in the circumferential direction of the frame area FA.

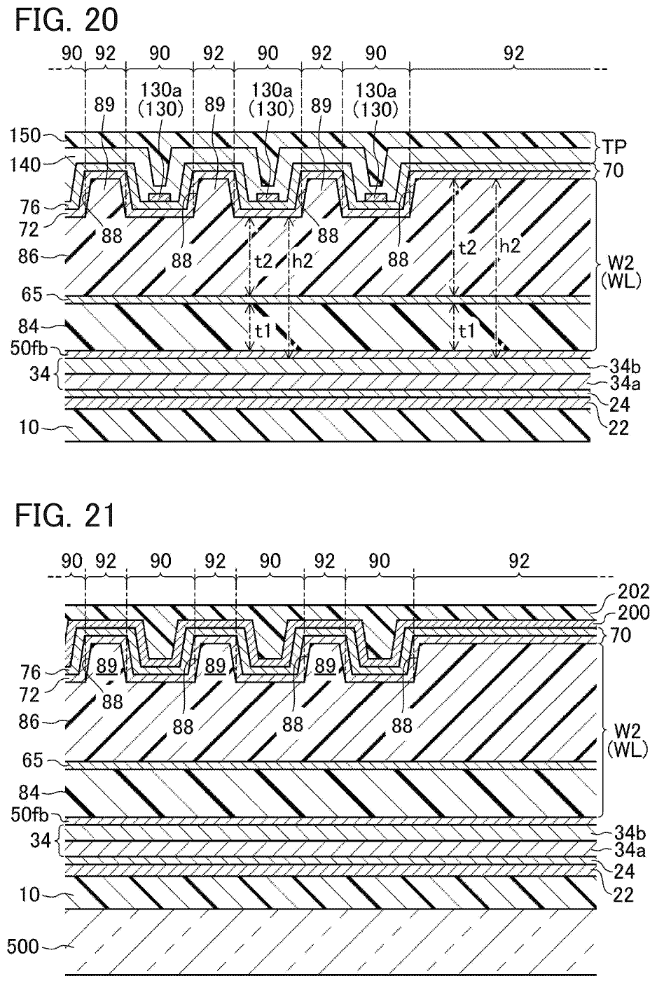

The low wall portions 90 of the first damming wall W1 and the second damming wall W2 (indicated by dot-hatching in FIG. 19) constitute only the portions where the touch panel lines 130 extend and the small-width portions that sit on both sides of these portions. In the first damming wall W1 and the second damming wall W2 in accordance with the present example, the thickness of the first wall layer 84 in the low wall portion 90 is equal to the thickness of the first wall layer 84 in the ordinary wall portion 92, whereas the thickness of the second wall layer 86 in the low wall portion 90 differs from the thickness of the second wall layer 86 in the ordinary wall portion 92 (FIG. 20 shows an example of the second damming wall W2). The second wall layer 86 in the low wall portion 90 is thinner than the second wall layer 86 in the ordinary wall portion 92 in both the first damming wall W1 and the second damming wall W2.

There is provided a protrusion 89 between the adjacent recesses 88 in the first damming wall W1 and the second damming wall W2. The portions of the first damming wall W1 and the second damming wall W2 that correspond to the protrusions 89 form the ordinary wall portions 92. In the circumferential direction of the frame area FA, the low wall portions 90 (recesses 88) correspond to each other, and the ordinary wall portions 92 (protrusions 89) correspond to each other, in the first damming wall W1 and the second damming wall W2. Each touch panel line 130 is provided so as to extend linearly between the first damming wall W1 and the second damming wall W2 and straddle the first damming wall W1 and the second damming wall W2 over the low wall portion 90.

This organic EL display device 1 is manufactured by similar processes as the embodiment above. To form the second wall layers 86 that form the first damming wall W1 and the second damming wall W2 in the manufacturing of the organic EL display device 1, similarly to the embodiment above, it is sufficient to form the recesses 88 in the second wall layer 86 by using, for example, a gray tone mask or a halftone mask and to form the low wall portion 90 and the ordinary wall portion 92 in those walls 82A and 82B at the same time as the formation of the first damming wall W1 and the second damming wall W2.

In addition, the first touch panel lines 130a and the second touch panel lines 130b are formed by common technology in the manufacturing of the organic EL display device 1. A description will be given below by taking as an example a step of forming the first touch panel lines 130a.

In a step of forming the first touch panel lines 130a, first, the electrically conductive transparent film 200 of, for example, indium tin oxide (ITO) is provided by, for example, sputtering on a substrate on which the sealing film 70 is formed. Next, referring to FIG. 21, the resist 202 is applied onto the substrate on which the electrically conductive transparent film 200 is formed, by a publicly known printing or coating technique such as spin-coating.

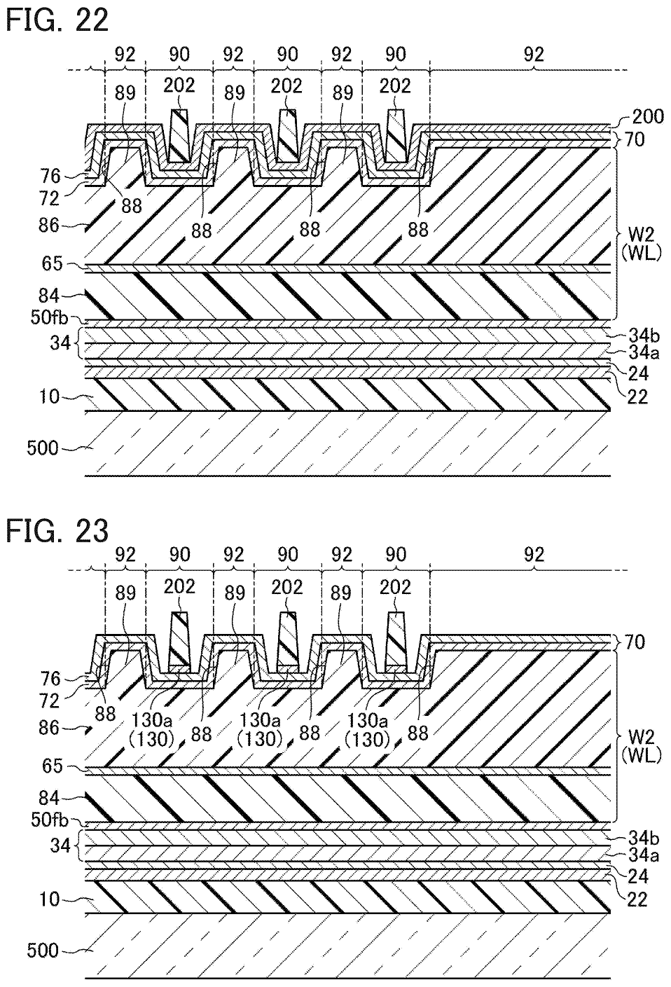

Subsequently, the resist 202 is patterned in regions including the individual recesses 88 (regions where the first detection electrodes 100, the first coupling lines 102, and the first touch panel lines 130a are formed) by subjecting the coating film of the resist 202 to pre-baking, exposure to light, development, and post-baking as shown in FIG. 22. Thereafter, as shown in FIG. 23, the electrically conductive transparent film 200 is patterned by etching using the resist 202 as a mask, to form the first touch panel lines 130a as well as the first detection electrodes 100 and the first coupling lines 102. Thereafter, the resist 202 is removed by, for example, ashing.

### Features of First Variation Example

In the organic EL display device 1 in accordance with this first variation example, a plurality of recesses 88 are provided separately for each touch panel line 130. This feature enables limiting the regions that are rendered the low wall portions 90 of the first damming wall W1 and the second damming wall W2 when compared with cases where the recesses 88 are provided contiguously across the portions where the plurality of touch panel lines 130 extend. Hence, the risk of the organic resin material leaking to outside the second damming wall W2 is reduced in forming the organic layer 74 in the manufacturing of the organic EL display device 1.

### Second Variation Example

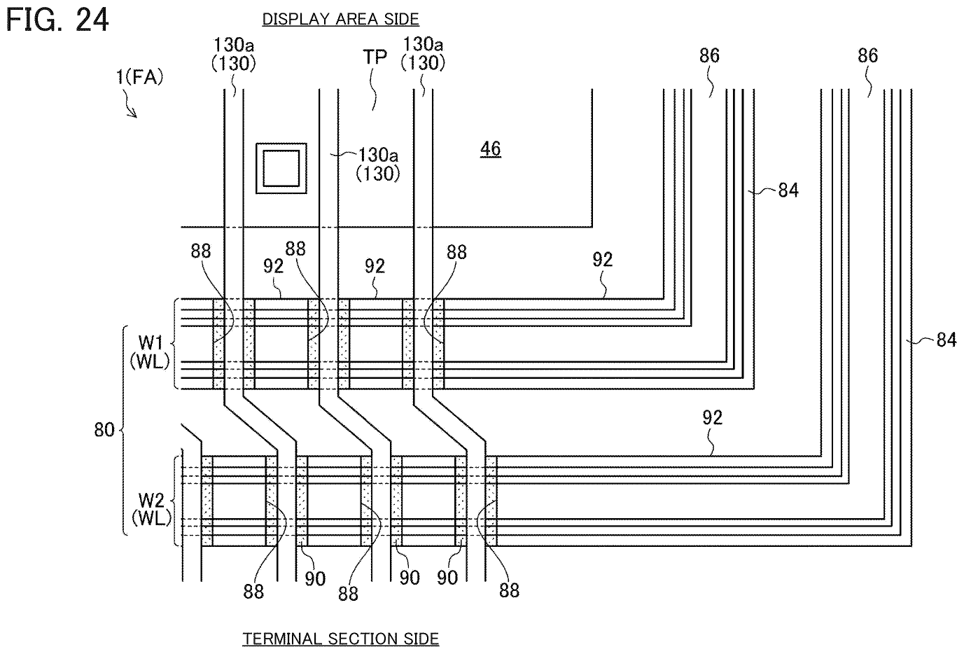

Referring to FIG. 24, in the organic EL display device 1 in accordance with this second variation example, the damming portion 80 includes the first damming wall W1 and the second damming wall W2. The recesses 88 in accordance with the present example are also provided in the first damming wall W1 and the second damming wall W2 respectively. Then, a plurality of recesses 88 are provided separately for each touch panel line 130 in the first damming wall W1 and the second damming wall W2. The recesses 88 in the first damming wall W1 and the recesses 88 in the second damming wall W2 are provided in mutually offset locations in the circumferential direction of the frame area FA.

The low wall portions 90 of the first damming wall W1 and the second damming wall W2 (indicated by dot-hatching in FIG. 24) constitute only the portions where the touch panel lines 130 extend and the small-width portions that sit on both sides of those portions. In the first damming wall W1 and the second damming wall W2 in accordance with the present example, the thickness of the first wall layer 84 in the low wall portion 90 is equal to the thickness of the first wall layer 84 in the ordinary wall portion 92, whereas the thickness of the second wall layer 86 in the low wall portion 90 differs from the thickness of the second wall layer 86 in the ordinary wall portion 92. The second wall layer 86 in the low wall portion 90 is thinner than the second wall layer 86 in the ordinary wall portion 92 in both the first damming wall W1 and the second damming wall W2.

There is provided a protrusion 89 between the adjacent recesses 88 in the first damming wall W1 and the second damming wall W2. The portions of the first damming wall W1 and the second damming wall W2 that correspond to the protrusions 89 form the ordinary wall portions 92. In the circumferential direction of the frame area FA, the low wall portion 90 of the first damming wall W1 corresponds to the ordinary wall portion 92 of the second damming wall W2, and the low wall portion 90 of the second damming wall W2 corresponds to the ordinary wall portion 92 of the first damming wall W1. The touch panel lines 130 are provided so as to bend between the first damming wall W1 and the second damming wall W2 and straddle the first damming wall W1 and the second damming wall W2 over the low wall portion 90.

### Features of Second Variation Example

In the organic EL display device 1 in accordance with this second variation example, the recesses 88 in the first damming wall W1 and the recesses 88 in the second damming wall W2 are provided in mutually offset locations in the circumferential direction of the frame area FA. This feature enables positioning the recesses 88 in the first damming wall W1 and the recesses 88 in the second damming wall W2 relatively far from each other and removing the recesses 88 in the second damming wall W2 from the distribution direction in which the organic resin material that will form the organic layer 74 flows in the recesses 88 in the first damming wall W1. Hence, the risk of the organic resin material leaking to outside the second damming wall W2 is further reduced in forming the organic layer 74 in the manufacturing of the organic EL display device 1.

### Third Variation Example

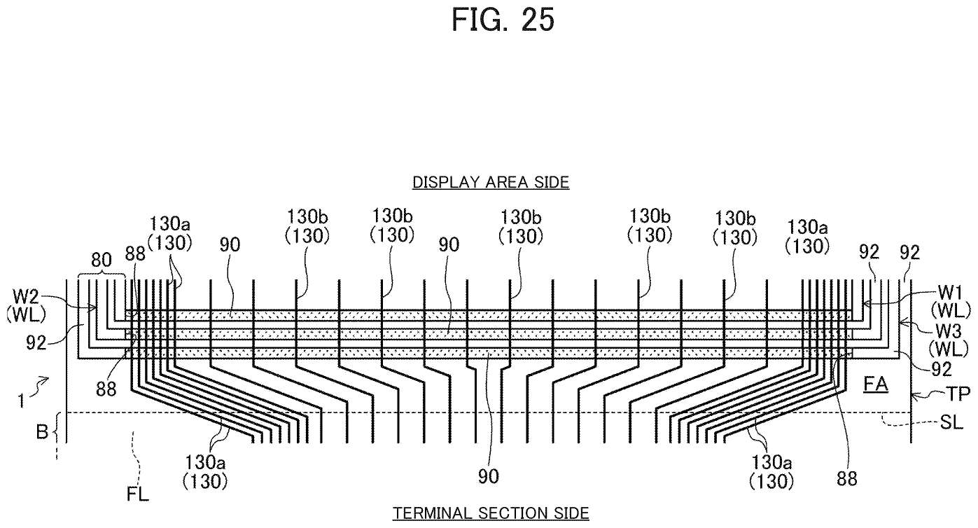

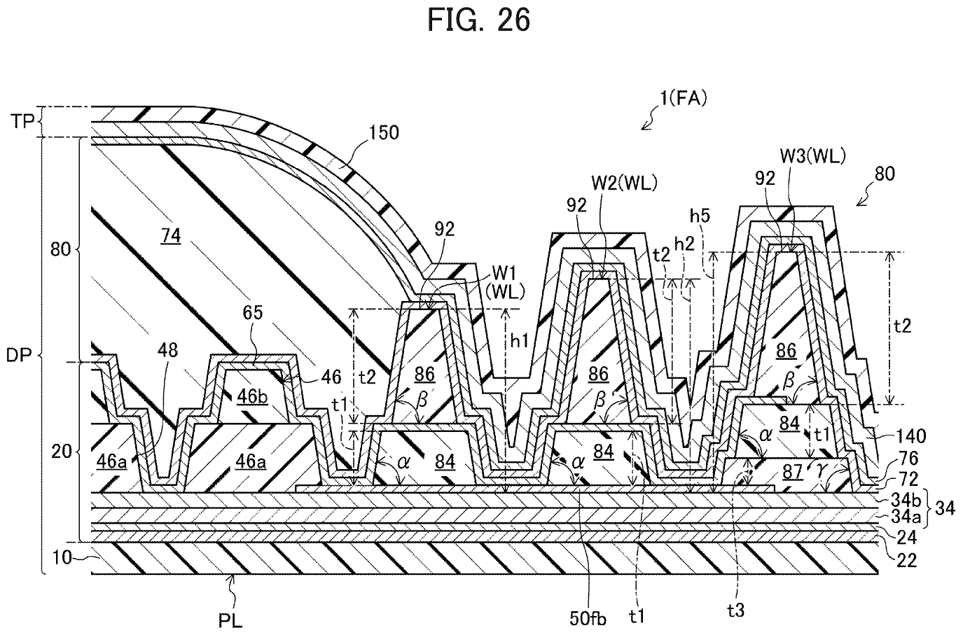

Referring to FIG. 25, in the organic EL display device 1 in accordance with this third variation example, the damming portion 80 includes a third damming wall W3 in addition to the first damming wall W1 and the second damming wall W2. The first damming wall W1 and the second damming wall W2 are formed by stacking the first wall layer 84 and the second wall layer 86. The third damming wall W3 includes a third wall layer 87 as well as the first wall layer 84 and the second wall layer 86. The third wall layer 87 is provided below the first wall layer 84. The third wall layer 87 is made of the same material, and provided in the same layer, as the first planarization film 46a.

The first damming wall W1, the second damming wall W2, and the third damming wall W3 have recesses 88. The recesses 88 are provided contiguously across the portions of the first damming wall W1, the second damming wall W2, and the third damming wall W3 where the plurality of touch panel lines 130 extend. The low wall portions 90 of the first damming wall W1, the second damming wall W2, and the third damming wall W3 that correspond to the recesses 88 (indicated by dot-hatching in FIG. 25) are lower in height than the ordinary wall portions 92 which are the other portions thereof.

Referring to FIG. 26, the height h2 of the ordinary wall portion 92 of the second damming wall W2 is larger than the height h1 of the ordinary wall portion 92 of the first damming wall W1. The height h3 of the ordinary wall portion 92 of the third damming wall W3 is larger than the height 2 of the ordinary wall portion 92 of the second damming wall W2. The thickness t2 of the second wall layer 86 that forms the ordinary wall portion 92 of the second damming wall W2 is larger than the thickness t2 of the second wall layer 86 that forms the ordinary wall portion 92 of the first damming wall W1. The thickness t2 of the second wall layer 86 that forms the ordinary wall portion 92 of the third damming wall W3 is equivalent to, or larger than, the thickness t2 of the second wall layer 86 that forms the ordinary wall portion 92 of the second damming wall W2.

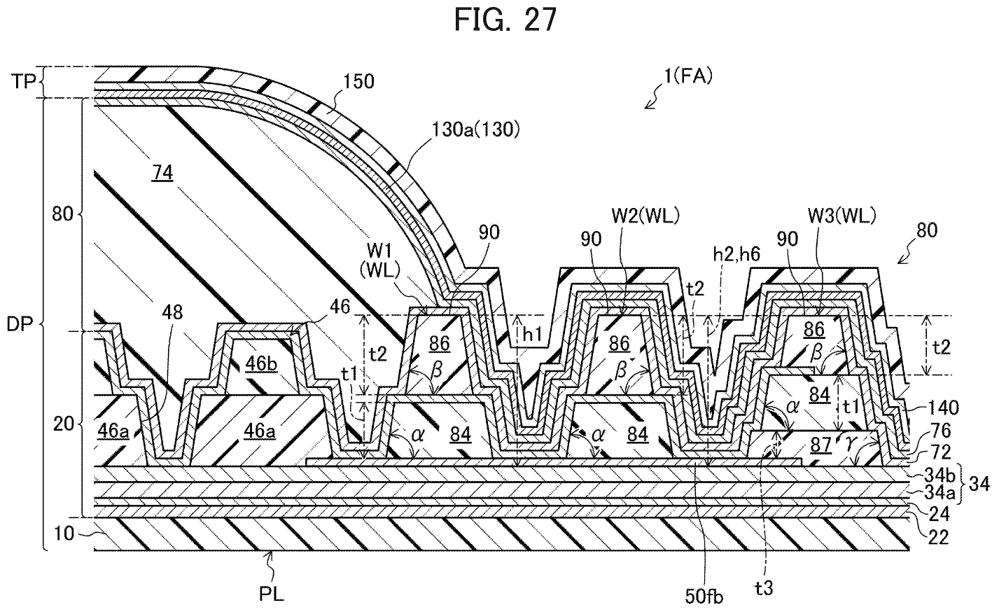

Referring to FIG. 27, the low wall portion 90 of the first damming wall W1, the low wall portion 90 of the second damming wall W2 and, the low wall portion 90 of the third damming wall W3 are, formed with the same height. In the first damming wall W1, the second damming wall W2, and the third damming wall W3 in accordance with the present example, the thickness of the first wall layer 84 in the low wall portion 90 is equivalent to the thickness of the first wall layer 84 in the ordinary wall portion 92, whereas the thickness of the second wall layer 86 in the low wall portion 90 differs from the thickness of the second wall layer 86 in the ordinary wall portion 92. In the first damming wall W1, the second damming wall W2, and the third damming wall W3, the second wall layer 86 that forms the low wall portion 90 is thinner than the second wall layer 86 that forms the ordinary wall portion 92.

In the third damming wall W3, the side faces make angles α, β, and γ each of approximately, for example, from 30° to 50° with the formation faces of the first wall layer 84, and the second wall layer 86, and the third wall layer 87 respectively. In the third damming wall W3, the height h6 of the low wall portion 90 is specified to approximately 55% to 62% the height h5 of the ordinary wall portion 92. For example, the height h5 of the ordinary wall portion 92 of the third damming wall W3 is approximately from 5.5 μm to 6.5 μm. In such a case, the height h6 of the low wall portion 90 of the third damming wall W3 is, for example, approximately from 3.0 μm to 4.0 μm.

### Other Embodiments

The recesses 88 are described as being provided contiguously in the portions where the plurality of touch panel lines 130 extend in the embodiments above, whereas in the second variation example and the third variation example, a plurality of recesses 88 are described as being provided separately for each touch panel line 130, which is by no means intended to limit the scope of the invention. Alternatively, the recesses 88 need only to be provided lower in height in the portions of the first damming wall W1 and the second damming wall W2 where the touch panel lines 130 extend than in the other portions thereof.

The thickness t1 of the first wall layer 84 in the low wall portion 90 is described as being equivalent to the thickness t1 of the first wall layer 84 in the ordinary wall portion 92, whereas the thickness t2 of the second wall layer 86 in the low wall portion 90 as differing from the thickness t2 of the second wall layer 86 in the ordinary wall portion 92, in both the first damming wall W1 and the second damming wall W2 in the embodiments above, which is by no means intended to limit the scope of the invention. Alternatively, the thickness t1 of the first wall layer 84 in the low wall portion 90 may differ from the thickness t1 of the first wall layer 84 in the ordinary wall portion 92, whereas the thickness t2 of the second wall layer 86 in the low wall portion 90 may be equivalent to the thickness t2 of the second wall layer 86 in the ordinary wall portion 92, in both the first damming wall W1 and the second damming wall W2. In such a case, the thickness t1 of the first wall layer 84 that forms the low wall portion 90 is smaller than the thickness t1 of the first wall layer 84 that forms the ordinary wall portion 92 of the first damming wall W1 and the second damming wall W2. In addition, the thickness t1 of the first wall layer 84 and the thickness t2 of the second wall layer 86 may both differ between the low wall portion 90 and the ordinary wall portion 92 of the first damming wall W1 and the second damming wall W2 respectively.

The recesses 88 are described as being provided in both the first damming wall W1 and the second damming wall W2 in the embodiments above, which is by no means intended to limit the scope of the invention. Alternatively, the recesses 88 may be provided only in the first damming wall W1 or only in the second damming wall W2.

The first damming wall W1 and the second damming wall W2 are each described as having a two-layered structure including the first wall layer 84 and the second wall layer 86 in the embodiments above, which is by no means intended to limit the scope of the invention. Alternatively, for example, the first damming wall W1 and the second damming wall W2 may each have a three-layered structure including the third wall layer 87, which is made of the same material, and provided in the same layer, as the first planarization film 46a, as is the case with the third damming wall W3 in accordance with the third variation example.

The first wall layer 84 is described as being made of the same material, and provided in the same layer, as the second planarization film 46b, and the second wall layer 86 as being made of the same material, and provided in the same layer, as the edge cover 66, in the embodiments above, which is by no means intended to limit the scope of the invention. Alternatively, the first wall layer 84 may be made of the same material, and provided in the same layer, as the first planarization film 46a. In such a case, the second wall layer 86 may be made of the same material, and provided in the same layer, as the second planarization film 46b.

The planarization film 46 of the display panel DP is described as including two layers, that is, the first planarization film 46a and the second planarization film 46b, in the embodiments above, which is by no means intended to limit the scope of the invention. Alternatively, the planarization film 46 may include a single layer. In such a case, for example, the first wall layer 84 is made of the same material, and provided in the same layer, as the planarization film 46, and the second wall layer 86 is made of the same material, and provided in the same layer, as the edge cover 66.

The organic EL layers 64 are described as being provided separately in each subpixel SP in the embodiments above, which is by no means intended to limit the scope of the invention. Alternatively, the organic EL layer 64 may be provided contiguously and commonly across the plurality of subpixels SP. In such a case, the organic EL display device 1 may achieve color displays in the subpixels SP by, for example, including a color filter.

Each pixel PX is described as including subpixels SP of three colors in the embodiments above, which is by no means intended to limit the scope of the invention. Alternatively, the subpixels SP in each pixel PX may have four or more colors instead of three colors. In addition, the three-color subpixels SP in each pixel PX have been described as being arranged in stripes, which is by no means intended to limit the scope of the invention. Alternatively, the plurality of subpixels SP may have another arrangement such as a PenTile arrangement.

The plurality of TFTs 30 in the pixel circuit PC are described as being three, that is, the first TFT 30A, the second TFT 30B, and the third TFT 30C, in the embodiments above, which is by no means intended to limit the scope of the invention. Alternatively, the plurality of TFTs 30 in the pixel circuit PC may be two, four, or more. In addition, the TFTs 30 are described as having a top gate structure in the embodiments above, which is by no means intended to limit the scope of the invention. Alternatively, the TFTs 30 may have a bottom gate structure.

The organic EL elements 62 are described as having a top-emission structure in the embodiments above, which is by no means intended to limit the scope of the invention. Alternatively, the organic EL elements 62 may have a bottom-emission structure in which the light emitted by the organic EL layer 64 is taken out through the substrate layer 10 side. In addition, the organic EL elements 62 may have a top-and bottom-emission structure in which the light emitted by the organic EL layer 64 is taken out through both the substrate layer 10 side and the sealing film 70 side.

The pixel electrode 63 is described as being an anode, and the common electrode 65 is described as being a cathode, in the embodiments above, which is by no means intended to limit the scope of the invention. Alternatively, the organic EL display device 1 may be structured so that the pixel electrode 63 functions as a cathode and the common electrode 65 functions as an anode. In such a case, the organic EL layer 64 has a reverse layered structure.

The organic EL layer 64 is described as having a five-layered structure including a hole injection layer, a hole transport layer, a light-emitting layer, an electron transport layer, and an electron injection layer in the embodiments above, which is by no means intended to limit the scope of the invention. Alternatively, the organic EL layer 64 may have a three-layered structure including a hole injection and transport layer, a light-emitting layer, and an electron transport and injection layer and may have any layered structure.

The organic EL display device 1 with a touch panel is discussed as an exemplary display device in the embodiments above, which is by no means intended to limit the scope of the invention. The technique of the present disclosure is applicable also to, for example, organic EL display devices with no touch panel TP. The technique of the present disclosure is useful in restraining breaking of wiring lines extending so as to straddle the first damming wall W1 and the second damming wall W2 even when the wiring lines are not the touch panel lines 130.

In addition, the technique of the present disclosure is applicable to display devices including a plurality of current-driven light-emitting elements. Examples of such a display device include display devices including QLEDs (quantum-dot light-emitting diodes), which are light-emitting elements using a quantum-dot-containing layer. The technique of the present disclosure is further applicable to, for example, liquid crystal display devices and plasma display devices.

Preferred embodiments and their variation examples have been described so far to illustrate the technology disclosed here. The technology disclosed here is however not limited to these embodiments and variation examples and applicable also to other embodiments that may involve, for example, suitable modification, replacement, addition, and/or omission. The embodiments above may be modified, where appropriate, without departing from the scope of the present disclosure, and all such modifications are encompassed in the scope of the present disclosure as would be understood by one skilled in the art.

### INDUSTRIAL APPLICABILITY

As described above, the technique of the present disclosure is useful in display devices.

### REFERENCE SIGNS LIST

DA Display Area
FA Frame Area
TP Touch Panel
WL Damming Wall
W1 First Damming Wall (First Wall Body, Wall Body)
W2 Second Damming Wall (Second Wall Body, Wall Body)
W3 Third Damming Wall (Wall Body)
1 Organic EL Display Device (Display Device)
10 Substrate Layer
20 TFT Layer (Thin Film Transistor Layer)
30 TFT (Thin Film Transistor)
46 Planarization Film
46a First Planarization Film (Planarization Film)
46b Second Planarization Film (Planarization Film)
60 Light-emitting Element Layer
62 Organic EL Element (Organic Electroluminescent Element)
63 Pixel Electrode
70 Sealing Film
74 Organic Layer (Coating Film)
84 First Wall Layer
86 Second Wall Layer
88 Recess
130 Touch Panel Line (Wiring Line)
130a First Touch Panel Line (Wiring Line)
130b Second Touch Panel Line (Wiring Line)

1. A display device having: a display area in which an image is displayed; and a frame area provided around the display area, the display device comprising, in the frame area:
a wall body shaped like a frame and provided around the display area; and
a wiring line extending so as to straddle the wall body from the display area side toward outside the frame area, wherein
the wall body has such a recess that a portion of the wall body where the wiring line extends is lower in height than another portion of the wall body.

2. The display device according to claim 1, wherein
the wiring line comprises a plurality of wiring lines provided so as to extend parallel to each other on the wall body, and
the recess is provided contiguously across portions of the wall body where the plurality of wiring lines extend.

3. The display device according to claim 2, wherein
the wall body comprises: a first wall body; and a second wall body provided along an outer circumference of the first wall body, and
the recess comprises a plurality of recesses provided in each of the first wall body and the second wall body.

4. The display device according to claim 1, wherein
the wiring line comprises a plurality of wiring lines provided so as to extend parallel to each other on the wall body, and
the recess comprises a plurality of recesses provided individually for each of the plurality of wiring lines.

5. The display device according to claim 4, wherein
the wall body comprises: a first wall body; and a second wall body provided along an outer circumference of the first wall body, and
the recess comprises a plurality of recesses provided in each of the first wall body and the second wall body.

6. The display device according to claim 5, wherein the recess in the first wall body and the recess in the second wall body are provided in mutually offset locations in a circumferential direction of the frame area.

7. The display device according to claim 1, wherein
the wall body includes: a first wall layer supported by a substrate layer; and a second wall layer provided on the first wall layer, and
in one or both of the first wall layer and the second wall layer, a portion corresponding to the recess is thinner than another portion.

8. The display device according to claim 1, wherein
internal to the wall body, there is provided a coating film spreading in the display area, and the wall body is a damming wall that dams up a liquid material in forming the coating film.

9. The display device according to claim 8, further comprising:
a substrate layer;
a light-emitting element layer supported by the substrate layer and containing a plurality of light-emitting elements; and
a sealing film provided on the light-emitting element layer so as to cover the plurality of light-emitting elements, wherein
the coating film is contained in the sealing film.

10. The display device according to claim 9, further comprising a thin film transistor layer provided between the substrate layer and the light-emitting element layer and containing a plurality of thin film transistors, wherein
the thin film transistor layer includes a planarization film provided so as to cover the plurality of thin film transistors,
the light-emitting element layer includes:
a plurality of pixel electrodes; and
an edge cover provided so as to separate the plurality of pixel electrodes,
the first wall layer is made of a same material, and provided in a same layer, as the planarization film, and
the second wall layer is made of a same material, and provided in a same layer, as the edge cover.

11. The display device according to claim, wherein the plurality of light-emitting elements are organic electroluminescence elements.

12. The display device according to claim 8, further comprising an on-cell touch panel overlying the coating film, wherein the wiring line is a touch panel line in the touch panel.
